(19) United States
(12) Patent Application Publication
(10) Pub. No.: US 2026/0255818 A1
(43) Pub. Date: Aug. 27, 2026

(54) TOUCH ELECTRODE STRUCTURE AND METHOD FOR PREPARING SAME, TOUCH PANEL, AND DISPLAY DEVICE

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Xiao WANG, Beijing (CN); Zhangmin WU, Beijing (CN); Chienpang HUANG, Beijing (CN)

(73) Assignees: Chengdu BOE Optoelectronics Technology Co., Ltd., Chengdu (CN); BOE TECHNOLOGY GROUP CO., LTD., Beijing (CN)

(21) Appl. No.: 18/995,161

(22) PCT Filed: Mar. 14, 2024
(86) PCT No.: PCT/CN2024/081587

§ 371 Date: Jan. 16, 2025

(30) Foreign Application Priority Data
Apr. 27, 2023 (CN) 202310477442.4

(51) Int. Cl. H10K 59/131; G06F 3/041; G06F 3/044; H10K 59/12; H10K 59/40

(52) U.S. Cl. CPC H10K 59/131; G06F 3/0412; G06F 3/04164; G06F 3/0446; H10K 59/1201; H10K 59/40; G06F 2203/04103; G06F 2203/04111; G06F 2203/04112

(57) ABSTRACT

Disclosed is a touch electrode structure. In a plurality of touch traces included in a first touch electrode and a second touch electrode that are insulated from each other in the touch electrode structure, a ratio of a first distance between a first touch trace and a second touch trace in a first direction to a second distance between the second touch trace and a third touch trace in a second direction is close to 1.

### CROSS-REFERENCE TO RELATED APPLICATIONS

The present disclosure is a U.S. national phase application based on PCT/CN2024/081587, filed on Mar. 14, 2024, which claims priority to Chinese Patent Application No. 202310477442.4, filed on Apr. 27, 2023, and entitled “TOUCH ELECTRODE STRUCTURE AND METHOD FOR PREPARING SAME, TOUCH PANEL, AND DISPLAY DEVICE”, both of which are incorporated by reference herein.

### TECHNICAL FIELD

The present disclosure relates to the field of display technologies, and in particular, relates to a touch electrode structure and a method for preparing the same, a touch panel, and a display device.

### BACKGROUND

A touch panel includes a display substrate, a touch electrode structure disposed on the display substrate, a driving circuit electrically connected to the touch electrode structure, and a detection circuit. The driving circuit may provide a driving signal for the touch electrode structure. When a user's finger approaches the touch electrode structure, the detection circuit can detect a change in a capacitive sensing signal of the touch electrode structure where the user's finger is located, and can determine the position where the sensing signal changes as the touch position.

### SUMMARY

Embodiments of the present disclosure provide a touch electrode structure and a method for preparing the same, a touch panel, and a display device. The technical solutions are as follows.

In one aspect, a touch electrode structure is provided. The touch electrode structure is applied in a touch panel, and includes a first touch electrode and a second touch electrode insulated from the first touch electrode; wherein the first touch electrode and the second touch electrode each include a plurality of touch traces, wherein the plurality of touch traces include a first touch trace, a second touch trace, and a third touch trace that are arranged sequentially and adjacent in a first direction, a ratio of a first distance between the first touch trace and the second touch trace in the first direction to a second distance between the second touch trace and the third touch trace in the first direction ranging from 0.9 to 1.1;
wherein the first direction is one arrangement direction of a plurality of sub-pixels that are arranged in an array and of a display substrate in the touch panel.

In some embodiments, the plurality of touch traces form a plurality of mesh structures with each of the mesh structures being in a hexagonal shape, the plurality of mesh structures including a first target mesh structure and a second target mesh structure that are arranged and adjacent in the first direction;
wherein the first touch trace is a touch trace, away from the second target mesh structure, of the first target mesh structure, the second touch trace is a touch trace shared by the first target mesh structure and the second target mesh structure, and the third touch trace is a touch trace, away from the first target mesh structure, of the second target mesh structure.

In some embodiments, the first direction is a column direction of the sub-pixels in the touch panel or a row direction of the sub-pixels in the touch panel.

In some embodiments, the plurality of mesh structures further include a third target mesh structure adjacent to both the first target mesh structure and the second target mesh structure, wherein the third target mesh structure and the second touch trace are arranged in a second direction, the second direction intersecting with the first direction; and
a touch trace shared by the third target mesh structure and the first target mesh structure intersects with both the first direction and the second direction, and a touch trace shared by the third target mesh structure and the second target mesh structure intersects with both the first direction and the second direction.

In some embodiments, the plurality of touch traces further include a fourth touch trace and a fifth touch trace that are arranged and adjacent in the first direction, wherein the fourth touch trace and the fifth touch trace are disposed on a side, away from the first touch trace, of the third touch trace, and the fourth touch trace and the third touch trace are adjacent in the first direction; and the plurality of touch traces form a plurality of first mesh structure groups and a plurality of second mesh structure groups, wherein the plurality of first mesh structure groups and the plurality of second mesh structure groups are arranged alternately in a second direction, the second direction being perpendicular to the first direction; wherein
each of the first mesh structure groups includes a fourth target mesh structure, a fifth target mesh structure, a sixth target mesh structure, and a seventh target mesh structure that are arranged sequentially and adjacent in the first direction, wherein the first touch trace is a touch trace, away from the fifth target mesh structure, of the fourth target mesh structure, the second touch trace is a touch trace shared by the fourth target mesh structure and the fifth target mesh structure, the third touch trace is a touch trace shared by the fifth target mesh structure and the sixth target mesh structure, the fourth touch trace is a touch trace shared by the sixth target mesh structure and the seventh target mesh structure, and the fifth touch trace is a touch trace, away from the sixth target mesh structure, of the seventh target mesh structure; and
each of the second mesh structure groups includes an eighth target mesh structure and a ninth target mesh structure that are arranged sequentially and adjacent in the first direction, wherein the first touch trace is also a touch trace, away from the ninth target mesh structure, of the eighth target mesh structure, the third touch trace is also a touch trace shared by the eighth target mesh structure and the ninth target mesh structure, and the fifth touch trace is also a touch trace, away from the eighth target mesh structure, of the ninth target mesh structure.

In some embodiments, a ratio of a third distance between the third touch trace and the fourth touch trace in the first direction to the first distance and a ratio of the third distance to the second distance both range from 0.9 to 1.1; a ratio of a fourth distance between the fourth touch trace and the fifth touch trace in the first direction to the first distance and a ratio of the fourth distance to the second distance both range from 0.9 to 1.1; and
a ratio of a fifth distance between the first touch trace and the third touch trace in the first direction to a sixth distance between the third touch trace and the fifth touch trace in the first direction ranges from 0.9 to 1.1.

In some embodiments, any mesh structure in the first mesh structure groups and the second mesh structure groups is in a quadrilateral shape; the plurality of touch traces further include a sixth touch trace, a seventh touch trace, and an eighth touch trace arranged and adjacent in the second direction; and the plurality of first mesh structure groups include a first target mesh structure group, and the plurality of second mesh structure groups include a second target mesh structure group adjacent to the first target mesh structure group; wherein
the sixth touch trace is a touch trace shared by a plurality of mesh structures in the first target mesh structure group on a side away from the second target mesh structure group, the seventh touch trace is a touch trace shared by the plurality of mesh structures in the first target mesh structure group and a plurality of mesh structure in the second target mesh structure group, and the eighth touch trace is a touch trace shared by a plurality of mesh structures in the second target mesh structure group on a side away from the first target mesh structure group; and
a ratio of a seventh distance between the sixth touch trace and the seventh touch trace in the second direction to an eighth distance between the seventh touch trace and the eighth touch trace in the second direction ranges from 0.9 to 1.1.

In some embodiments, the plurality of touch traces form a plurality of mesh structures with each of the mesh structures being in a quadrilateral shape; wherein
the plurality of mesh structures include a tenth target mesh structure and an eleventh target mesh structure arranged and adjacent in the first direction, wherein the first touch trace is a touch trace, away from the eleventh target mesh structure, of the tenth target mesh structure, the second touch trace is a touch trace shared by the tenth target mesh structure and the eleventh target mesh structure, and the third touch trace is a touch trace, away from the tenth target mesh structure, of the eleventh target mesh structure.

In some embodiments, the plurality of touch traces further include a sixth touch trace, a seventh touch trace, and an eighth touch trace that are arranged sequentially and adjacent in a second direction; wherein
a ratio of a seventh distance between the sixth touch trace and the seventh touch trace in the second direction to an eighth distance between the seventh touch trace and the eighth touch trace in the second direction ranges from 0.9 to 1.1.

In some embodiments, the plurality of touch traces further include a ninth touch trace and a tenth touch trace; wherein
each of the ninth touch trace and the tenth touch trace is any one touch trace other than the second touch trace in the plurality of touch traces, and the ninth touch trace and the tenth touch trace are arranged and adjacent in the first direction; and
a ratio of a distance between the ninth touch trace and the tenth touch trace in the first direction to the first distance and a ratio of the distance between the ninth touch trace and the tenth touch trace in the first direction to the second distance both range from 0.9 to 1.1.

In some embodiments, the display substrate in the touch panel includes the plurality of sub-pixels and a plurality of sensors; a plurality of mesh structures formed by the plurality of touch traces include a sub-pixel target mesh structure and a sensor target mesh structure, the sub-pixel target mesh structure surrounding a light-emitting region of at least one of the sub-pixels, and the sensor target mesh structure surrounding at least one of the sensors; wherein
the sub-pixel target mesh structure includes an eleventh touch trace and a twelfth touch trace arranged in the first direction, and the sensor target mesh structure includes a thirteenth touch trace and a fourteenth touch trace arranged in the first direction;
wherein a ratio of a ninth distance between the eleventh touch trace and the twelfth touch trace in the first direction to a tenth distance between the thirteenth touch trace and the fourteenth touch trace in the first direction ranges from 0.9 to 1.1.

In some embodiments, a ratio of the ninth distance to the first distance and a ratio of the ninth distance to the second distance both range from 0.9 to 1.1; and
a ratio of the tenth distance to the first distance and a ratio of the tenth distance to the second distance both range from 0.9 to 1.1.

In another aspect, a method for preparing a touch electrode structure is provided. The touch electrode structure is applied in a touch panel, and includes a first touch electrode and a second touch electrode insulated from the first touch electrode; and the method includes:
forming a touch electrode film; and
acquiring a plurality of touch traces included in the first touch electrode and/or the second touch electrode by patterning the touch electrode film using a mask, wherein the plurality of touch traces include a first touch trace, a second touch trace and a third touch trace that are arranged sequentially in a first direction, and a ratio of a first distance between the first touch trace and the second touch trace in the first direction to a second distance between the second touch trace and the third touch trace in the first direction ranges from 0.9 to 1.1; wherein the first direction includes one arrangement direction of a plurality of sub-pixels that are arranged in an array and of a display substrate in the touch panel.

In some embodiments, the plurality of sub-pixels of the display substrate in the touch panel form a plurality of pixels, and each of the pixels includes one first color sub-pixel, one second color sub-pixel, and one third color sub-pixel; the mask is provided with a plurality of openings for forming the plurality of touch traces; and a design process of a target opening in the plurality of openings includes:
positioning a center of a first dummy reference pattern to overlap with a center of a light-emitting region of the first color sub-pixel, positioning a center of a second dummy reference pattern to overlap with a center of a light-emitting region of the second color sub-pixel, positioning a center of a third dummy reference pattern to overlap with a center of a light-emitting region of the third color sub-pixel, wherein a shape and a size of each dummy reference pattern are a same, and the shape and size of each dummy reference pattern are determined based on a shape and a size of a light-emitting region of each of the first color sub-pixel, the second color sub-pixel, and the third color sub-pixel; and the first dummy reference pattern, the second dummy reference pattern, and the third dummy reference pattern have a first target reference pattern and a second target reference pattern that are adjacent; and
designing a target opening in a region, of the mask, between the first target reference pattern and the second target reference pattern, and a distance between the target opening and the first target reference pattern is equal to a distance between the target opening and the second target reference pattern.

In some embodiments, the plurality of sub-pixels of the display substrate in the touch panel form a plurality of pixels, each of the pixels includes one first color sub-pixel, one second color sub-pixel, and one third color sub-pixel, and the display substrate further includes a plurality of sensors; the mask is provided with a plurality of openings for forming the plurality of touch traces; and a design process of a target opening in the plurality of openings includes:
positioning a center of a first dummy reference pattern to overlap with a center of a light-emitting region of the first color sub-pixel, positioning a center of a second dummy reference pattern to overlap with a center of a light-emitting region of the second color sub-pixel, positioning a center of a third dummy reference pattern to overlap with a center of a light-emitting region of the third color sub-pixel, positioning a center of a fourth dummy reference pattern to overlap with a center of a light-emitting region of one of the sensors, wherein a shape and a size of each dummy reference pattern are a same, and the shape and size of each dummy reference pattern are determined based on a shape and a size of a light-emitting region of each of the first color sub-pixel, the second color sub-pixel, and the third color sub-pixel; a the first dummy reference pattern, the second dummy reference pattern, the third dummy reference pattern, and the fourth dummy reference pattern have a first target reference pattern and a second target reference pattern that are adjacent; and
designing a target opening in a region, of the mask, between the first target reference pattern and the second target reference pattern, wherein a distance between the target opening and the first target reference pattern is equal to a distance between the target opening and the second target reference pattern.

In some embodiments, each of the pixels includes one first color sub-pixel, one second color sub-pixel, and one third color sub-pixel; wherein a shape of a light-emitting region of the first color sub-pixel, a shape of a light-emitting region of the second color sub-pixel, and a shape of a light-emitting region of the third color sub-pixel are a same; and an area of the light-emitting region of the first color sub-pixel, an area of the light-emitting region of the second color sub-pixel, and an area of the light-emitting region of the third color sub-pixel are reduced sequentially;
the shape of each dummy reference pattern is the same as the shape of the light-emitting region of the first color sub-pixel, and an area of each dummy reference pattern is greater than or equal to the area of the light-emitting region of the first color sub-pixel.

In some embodiments, a length of each dummy reference pattern in the first direction is greater than or equal to the longest length among a length of the light-emitting region of the first color sub-pixel in the first direction, a length of the light-emitting region of the second color sub-pixel in the first direction, and a length of the light-emitting region of the third color sub-pixel in the first direction;
a length of each dummy reference pattern in a second direction is greater than or equal to the longest length among a length of the light-emitting region of the first color sub-pixel in the second direction, a length of the light-emitting region of the second color sub-pixel in the second direction, and a length of the light-emitting region of the third color sub-pixel in the second direction, the second direction being perpendicular to the first direction; and
the shape of the dummy reference pattern is the same as at least one of the light-emitting region of the first color sub-pixel, the light-emitting region of the second color sub-pixel, or the light-emitting region of the third color sub-pixel.

In some embodiments, each of the pixel includes one first color sub-pixel, one second color sub-pixel, and two third color sub-pixels, and a distance between light-emitting regions of the two third color sub-pixels is less than 14 microns;
a length of each dummy reference pattern in a first direction is a first target length, the first target length being greater than or equal to the longest length among a length of the light-emitting region of the first color sub-pixel in the first direction, a length of the light-emitting region of the second color sub-pixel in the first direction, and a length of the target pattern in the first direction; wherein the target pattern is a minimum external pattern of the light-emitting regions of the two third color sub-pixels, a shape of the minimum external pattern being the same as a shape of the light-emitting region of the first color sub-pixel, and/or the shape of the minimum external pattern being the same as a shape of the light-emitting region of the second color sub-pixel;
a length of each dummy reference pattern in a second direction is a second target length, wherein the second target length is greater than or equal to the longest length among a length of the light-emitting region of the first color sub-pixel in the second direction, a length of the light-emitting region of the second color sub-pixel in the second direction, and a length of the target pattern in the second direction, the second direction being perpendicular to the first direction; and
the shape of the dummy reference pattern is the same as at least one of a light-emitting region of the first color sub-pixel, a light-emitting region of the second color sub-pixel, or the target pattern.

In yet another aspect, a touch panel is provided. The touch panel includes a display substrate and the touch electrode structure as described in the above aspect, wherein the touch electrode structure is disposed on the display substrate.

In some embodiments, the display substrate includes a plurality of sub-pixels that are arranged in an array and form a plurality of pixels, each of the pixels including one first color sub-pixel, one second color sub-pixel, and one third color sub-pixel, wherein a shape of a light-emitting region of the first color sub-pixel, a shape of a light-emitting region of the second color sub-pixel, and a shape of a light-emitting region of the third color sub-pixel are the same; and the plurality of touch traces in the touch electrode structure form a plurality of mesh structures, wherein the plurality of mesh structures include a plurality of sub-pixel target mesh structures, each of the sub-pixel target mesh structures surrounding a light-emitting region of one sub-pixel;
wherein a minimum distance, in a first direction, between the light-emitting region of the sub-pixel and a touch trace in a sub-pixel target mesh structure surrounding the light-emitting region of the sub-pixel is negatively correlated with an area of the light-emitting region of the sub-pixel, the first direction including one arrangement direction of the plurality of sub-pixel arranged in an array.

In some embodiments, the display substrate includes a plurality of sub-pixels that are arranged in an array and form a plurality of pixels, each of the pixels includes one first color sub-pixel, one second color sub-pixel, and one third color sub-pixel; and the plurality of touch traces in the touch electrode structure form a plurality of mesh structures, wherein the plurality of mesh structures include a plurality of sub-pixel target mesh structures, each of the sub-pixel target mesh structures surrounding a light-emitting region of at least one sub-pixel;
wherein a minimum distance, in a first direction, between the light-emitting region of the sub-pixel and a touch trace in a sub-pixel target mesh structure surrounding the light-emitting region of the sub-pixel is negatively correlated with a length of the light-emitting region of the sub-pixel in the first direction, the first direction including one arrangement direction of the plurality of sub-pixel arranged in an array.

In some embodiments, each of the pixels includes one first color sub-pixel, one second color sub-pixel, and two third color sub-pixels, and a distance between light-emitting regions of the two third color sub-pixels is less than 14 microns; and
the plurality of sub-pixel target mesh structures include a first-type mesh structure and a second-type mesh structure, wherein the first-type mesh structure surrounds a light-emitting region of the one first color sub-pixel or a light-emitting region of the one second color sub-pixel, the second-type mesh structure surrounds light-emitting regions of the two third color sub-pixels, and the light-emitting regions of two third color sub-pixels surrounded by the second-type mesh structure are arranged in a second direction, the second direction being perpendicular to the first direction.

In some embodiments, the display substrate further includes a plurality of sensors; and the plurality of mesh structures further include a plurality of sensor target mesh structures, each of the sensor target mesh structures surrounding one sensor;
wherein a minimum distance, in a first direction, between the sensor and a touch trace in a sensor target mesh structure surrounding the sensor is negatively correlated with a length of the sensor in the first direction.

In still another aspect, a touch display device is provided. The touch display includes a power supply assembly and the touch panel as described in the above aspect;
wherein the power supply assembly is configured to supply power to the touch panel.

### BRIEF DESCRIPTION OF THE DRAWINGS

To describe the technical solutions in the embodiments of the present disclosure more clearly, the following briefly introduces the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a partial cross-sectional schematic diagram of a touch panel according to some embodiments of the present disclosure;

FIG. 2 is a partial top view of a touch electrode structure according to some embodiments of the present disclosure;

FIG. 3 is a partial top view of another touch electrode structure according to some embodiments of the present disclosure;

FIG. 4 is a partial top view of yet another touch electrode structure according to some embodiments of the present disclosure;

FIG. 5 is a partial top view of still another touch electrode structure according to some embodiments of the present disclosure;

FIG. 6 is a partial top view of still another touch electrode structure according to some embodiments of the present disclosure;

FIG. 7 is a partial top view of still another touch electrode structure according to some embodiments of the present disclosure;

FIG. 8 is a schematic diagram of a sensor target mesh structure and a sub-pixel target mesh structure according to some embodiments of the present disclosure;

FIG. 9 is a partial cross-sectional schematic diagram of yet another touch panel according to some embodiments of the present disclosure;

FIG. 10 is a flowchart of a method for preparing a touch electrode structure according to some embodiments of the present disclosure;

FIG. 11 is a partial top view of a display substrate according to some embodiments of the present disclosure;

FIG. 12 is a schematic diagram of providing a dummy reference pattern according to some embodiments of the present disclosure;

FIG. 13 is a partial top view of another display substrate according to some embodiments of the present disclosure;

FIG. 14 is a schematic diagram of another type of providing a dummy reference pattern according to some embodiments of the present disclosure;

FIG. 15 is a partial top view of yet another display substrate according to some embodiments of the present disclosure;

FIG. 16 is a schematic diagram of yet another type of providing a dummy reference pattern according to some embodiments of the present disclosure;

FIG. 17 is a schematic diagram of still another type of providing a dummy reference pattern according to some embodiments of the present disclosure;

FIG. 18 is a schematic diagram of still another type of providing a dummy reference pattern according to some embodiments of the present disclosure;

FIG. 19 is a schematic diagram of still another type of providing a dummy reference pattern according to some embodiments of the present disclosure;

FIG. 20 is a schematic diagram of still another type of providing a dummy reference pattern according to some embodiments of the present disclosure;

FIG. 21 is a schematic diagram of still another type of providing a dummy reference pattern according to some embodiments of the present disclosure;

FIG. 22 is a partial top view of a touch electrode structure and a light-emitting region of a sub-pixel according to some embodiments of the present disclosure;

FIG. 23 is a partial top view of a touch electrode structure and a light-emitting region of a sub-pixel in the related art;

FIG. 24 is a partial top view of another touch electrode structure and a light-emitting region of a sub-pixel according to some embodiments of the present disclosure;

FIG. 25 is a partial top view of another touch electrode structure and a light-emitting region of a sub-pixel in the related art;

FIG. 26 is a partial top view of yet another touch electrode structure and light-emitting region of a sub-pixel according to some embodiments of the present disclosure;

FIG. 27 is a partial top view of yet another touch electrode structure and a light-emitting region of a sub-pixel in the related art;

FIG. 28 is a partial top view of still another touch electrode structure and light-emitting region of a sub-pixel according to some embodiments of the present disclosure;

FIG. 29 is a partial top view of still another touch electrode structure and a light-emitting region of a sub-pixel in the related art;

FIG. 30 is a partial top view of still another touch electrode structure and a light-emitting region of a sub-pixel according to some embodiments of the present disclosure;

FIG. 31 is a partial top view of still another touch electrode structure and a light-emitting region of a sub-pixel in the related art;

FIG. 32 is a partial cross-sectional schematic diagram of yet another touch panel according to some embodiments of the present disclosure; and

FIG. 33 is a schematic structural diagram of a display device according to some embodiments of the present disclosure.

### DETAILED DESCRIPTION

For clearer descriptions of the objectives, technical solutions, and advantages of the present disclosure, embodiments of the present disclosure are described in detail hereafter with reference to the accompanying drawings.

With the rapid development of organic light emitting diode (OLED) display panels, mobile terminals have entered the era of full-screen and folding screen. In order to bring a better user experience, full screen, narrow bezel screen, high-resolution screen, and folding screen will become an important development direction of OLED display panels in the future. In order to make the display panel lighter and thinner to adapt to folding and curling products, flexible multi-layer on-cell touch technology (FMLOC) was born. Moreover, with the continuous development of information technology, higher and higher requirements are placed on the touch performance of touch panels.

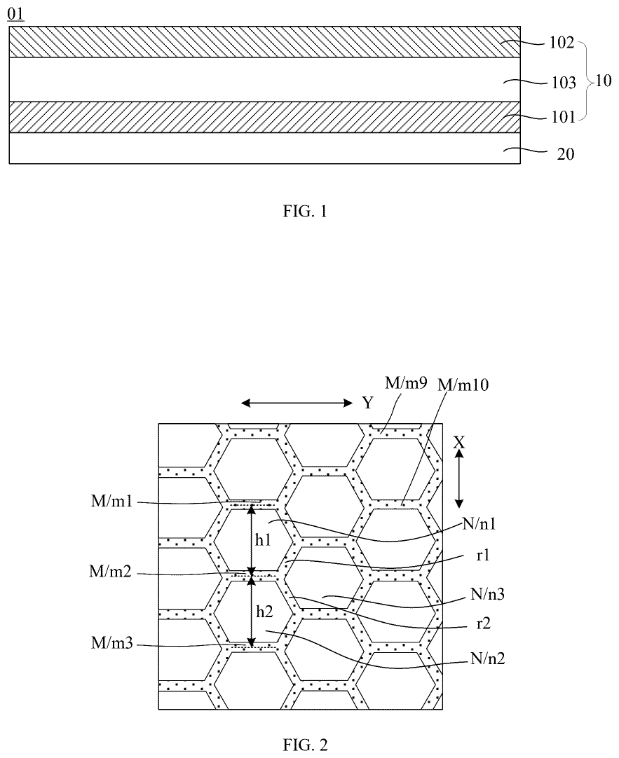

FIG. 1 is a partial cross-sectional schematic diagram of a touch electrode panel according to some embodiments of the present disclosure. The touch electrode structure 10 can be applied in the touch panel 01, and the touch electrode structure 10 is designed to be disposed on a base substrate. As can be seen with reference to FIG. 1, the touch electrode structure 10 includes a first touch electrode 101, and a second touch electrode 102 that is insulated from the first touch electrode 101. For example, an insulating film layer 103 is arranged between the first touch electrode 101 and the second touch electrode 102. Thus, the signal transmitted in the first touch electrode 101 can be made different from the signal transmitted in the second touch electrode 102.

In the embodiments of the present disclosure, the first touch electrode 101 and the second touch electrode 102 each include a plurality of touch traces M. FIG. 2 is a partial top view of a touch electrode according to some embodiment of the present disclosure. Referring to FIG. 2, the plurality of touch traces M includes at least a first touch trace m1, a second touch trace m2, and a third touch trace m3 that are arranged sequentially in a first direction X and adjacent to each other. A ratio of a first distance h1 between the first touch trace m1 and the second touch trace m2 in the first direction X to a second distance h2 between the second touch trace m2 and the third touch trace m3 in the first direction X ranges from 0.9 to 1.1. That is, the ratio of the first distance h1 of the first touch trace m1 and the second touch trace m2 in the first direction X to the second distance h2 of the second touch trace m2 and the third touch trace m3 in the first direction X is close to 1, and the first distance h1 is approximately equal to the second distance h2.

The first direction X may be an arrangement direction of the plurality of sub-pixels that are arranged in an array and being of the display substrate in the touch panel. For example, the first direction X may be a column direction of the sub-pixels or a row direction of the sub-pixels.

Since the first distance h1 between the first touch trace m1 and the second touch trace m2 in the first direction X and the second distance h2 between the second touch trace m2 and the third touch trace m3 in the first direction X are approximately equal, the first touch trace m1, the second touch trace m2, and the third touch trace m3 can be arranged more uniformly, which improves the uniformity of the field strength of the touch panel 01, and thus improves the uniformity and sensitivity of the capacitive sensing signal of the touch panel 01. In this way, the touch effect of the touch panel 01 can be improved, and visibility problems of the display device can be avoided simultaneously.

In the embodiments of the present disclosure, the distance between the two touch traces may be a distance between the centerlines of the two touch traces. The extension direction of the centerline of the touch trace is the same as the extension direction of the touch trace. Exemplarily, the first distance h1 between the first touch trace m1 and the second touch trace m2 in the first direction X may refer to a distance between the centerline of the first touch trace m1 and the centerline of the second touch trace m2 in the first direction X.

In summary, the embodiments of the present disclosure provide a touch electrode structure. In a plurality of touch traces included in a first touch electrode and in a second touch electrode that are insulated from each other in the touch electrode structure, a ratio of a first distance between a first touch trace and a second touch trace in a first direction to a second distance between the second touch trace and a third touch trace in a second direction is close to 1. That is, the first touch trace, the second touch trace, and the third touch trace that are arranged in the first direction and adjacent to each other are arranged more uniformly, which can improve the uniformity of the field strength of the touch panel, improve the uniformity and sensitivity of the capacitive sensing signal of the touch panel, thereby improving the touch effect of the touch panel, and avoiding visibility problems of the display device simultaneously. Avoiding visibility problems of the display device can mean avoiding users from observing abnormal display of the display device.

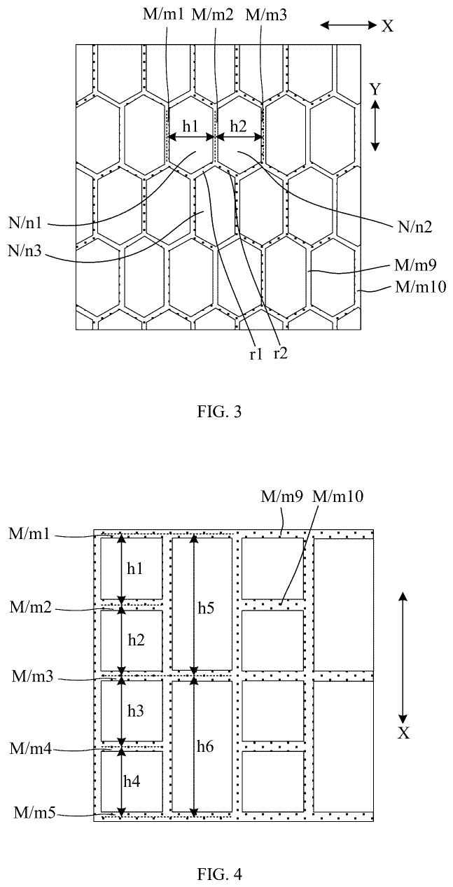

In a first optional implementation, referring to FIG. 2 and FIG. 3, the plurality of touch traces M form a plurality of mesh structures N with each of the mesh structures being in a hexagonal shape. The plurality of mesh structures N include at least a first target mesh structure n1 and a second target mesh structure n2 arranged in the first direction X and adjacent to each other.

The first touch trace m1 is a touch trace of the first target mesh structure n1 away from the second target mesh structure n2. The second touch trace m2 is a touch trace shared by the first target mesh structure n1 and the second target mesh structure n2. The third touch trace m3 is a touch trace of the second target mesh structure n2 away from the first target mesh structure n1.

That is, the width of the first target mesh structure n1 in the first direction X may be the first distance h1 between the first touch trace m1 and the second touch trace m2 in the first direction X. The width of the second target mesh structure n2 in the first direction X may be the second distance h2 between the second touch trace m2 and the third touch trace m3 in the first direction X.

In the embodiments of the present disclosure, the plurality of mesh structures N also includes a third target mesh structure n3 adjacent to both the first target mesh structure n1 and the second target mesh structure n2. The third target mesh structure n3 and the second touch trace m2 (a touch trace shared by the first target mesh structure n1 and the second target mesh structure n2) are arranged in the second direction Y. The second direction Y and the first direction X intersect.

The touch trace r1 shared by the third target mesh structure n3 and the first target mesh structure n1 intersects with both the first direction X and the second direction Y. And the touch trace r2 shared by the third target mesh structure n3 and the second target mesh structure n2 intersects with both the first direction X and the second direction Y.

Referring to FIG. 2, the first direction X is a column direction of the sub-pixels in the touch panel, and the second direction Y is a row direction of the sub-pixels in the touch panel. Alternatively, referring to FIG. 3, the first direction X is the row direction of the sub-pixels in the touch panel, and the second direction Y is the column direction of the sub-pixels in the touch panel.

In a second optional implementation, referring to FIG. 4, the plurality of touch traces M also includes a fourth touch trace m4 and a fifth touch trace m5 that are arranged in the first direction X and adjacent to each other. The fourth touch trace m4 and the fifth touch trace m5 are disposed on the side of the third touch trace m3 away from the first touch trace m1, and the fourth touch trace m4 and the third touch trace m3 are adjacent in the first direction X. That is, the first touch trace m1, the second touch trace m2, the third touch trace m3, the fourth touch trace m4, and the fifth touch trace m5 are arranged sequentially in the first direction X.

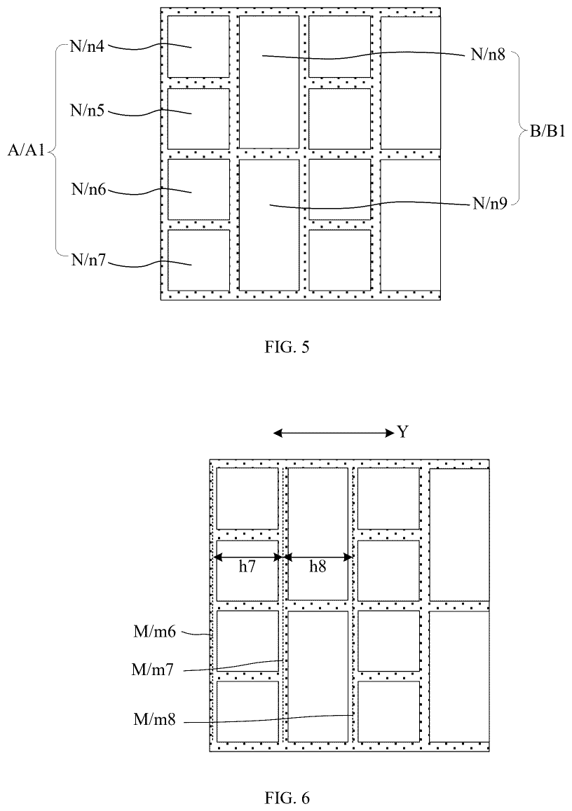

Referring to FIG. 5, the plurality of touch traces M form a plurality of first mesh structure groups A and a plurality of second mesh structure groups B, and the plurality of first mesh structure groups A and the plurality of second mesh structure groups B are arranged alternately in the second direction Y.

The first mesh structure group A includes at least a fourth target mesh structure n4, a fifth target mesh structure n5, a sixth target mesh structure n6, and a seventh target mesh structure n7 that are arranged sequentially in the first direction X and adjacent to each other. The fourth target mesh structure n4, the fifth target mesh structure n5, the sixth target mesh structure n6, and the seventh target mesh structure n7 may form the five touch traces arranged sequentially in the first direction X as described above.

In some embodiments, the first touch trace m1 is a touch trace of the fourth target mesh structure n4 away from the fifth target mesh structure n5. The second touch trace m2 is a touch trace shared by the fourth target mesh structure n4 and the fifth target mesh structure n5. The third touch trace m3 is a touch trace shared by the fifth target mesh structure n5 and the sixth target mesh structure n6. The fourth touch trace m4 is a touch trace shared by the sixth target mesh structure n6 and the seventh target mesh structure n7. The fifth touch trace m5 is a touch trace of the seventh target mesh structure n7 away from the sixth target mesh structure n6.

The second mesh structure group B includes at least an eighth target mesh structure n8 and a ninth target mesh structure n9 that are arranged sequentially in the first direction X and adjacent to each other. The eighth target mesh structure n8 and the ninth target mesh structure n9 may form the first touch trace m1, the third touch trace m3, and the fifth touch trace m5 that are arranged sequentially in the first direction X as described above.

In some embodiments, the first touch trace ml is also a touch trace of the eighth target mesh structure n8 away from the ninth target mesh structure n9. The third touch trace m3 is also a touch trace shared by the eighth target mesh structure n8 and the ninth target mesh structure n9. The fifth touch trace m5 is also a touch trace of the ninth target mesh structure n9 away from the eighth target mesh structure n8.

As can be seen from the above design, the width of the fourth target mesh structure n4 in the first direction X may be the first distance h1 between the first touch trace m1 and the second touch trace m2 in the first direction X. The width of the fifth target mesh structure n5 in the first direction X may be the second distance h2 between the second touch trace m2 and the third touch trace m3 in the first direction X. The width of the sixth target mesh structure n6 in the first direction X may be a third distance h3 between the third touch trace m3 and the fourth touch trace m4 in the first direction X. The width of the seventh target mesh structure n7 in the first direction X may be a fourth distance h4 between the fourth touch trace m4 and the fifth touch trace m5 in the first direction X. The width of the eighth target mesh structure n8 in the first direction X may be a fifth distance h5 between the first touch trace m1 and the third touch trace m3 in the first direction X. The width of the ninth target mesh structure n9 in the first direction X may be a sixth distance h6 between the third touch trace m3 and the fifth touch trace m5 in the first direction X.

That is, the sum of the lengths of the fourth target mesh structure n4 and the fifth target mesh structure n5 in the first direction X is equal to the length of the eighth target mesh structure n8 in the first direction X. The sum of the lengths of the sixth target mesh structure n6 and the seventh target mesh structure n7 in the first direction X is equal to the length of the ninth target mesh structure n9 in the first direction X.

In the embodiments of the present disclosure, a ratio of the third distance h3 between the third touch trace m3 and the fourth touch trace m4 in the first direction X to the first distance h1 and a ratio of the third distance h3 to the second distance h2 both range from 0.9 to 1.1. The fourth distance h4 between the fourth touch trace m4 and the fifth touch trace m5 in the first direction X to the first distance h1 and a ratio of the fourth distance h4 to the second distance h2 both range from 0.9 to 1.1. In addition, a ratio of the fifth distance h5 between the first touch trace m1 and the third touch trace m3 in the first direction X to the sixth distance h6 between the third touch trace m3 and the fifth touch trace m5 in the first direction X ranges from 0.9 to 1.1.

That is, the first touch trace m1, the second touch trace m2, the third touch trace m3, the fourth touch trace m4, and the fifth touch trace m5 are arranged more uniformly in the first direction X. The uniformity of the field strength of the touch panel 01 can thus be further improved.

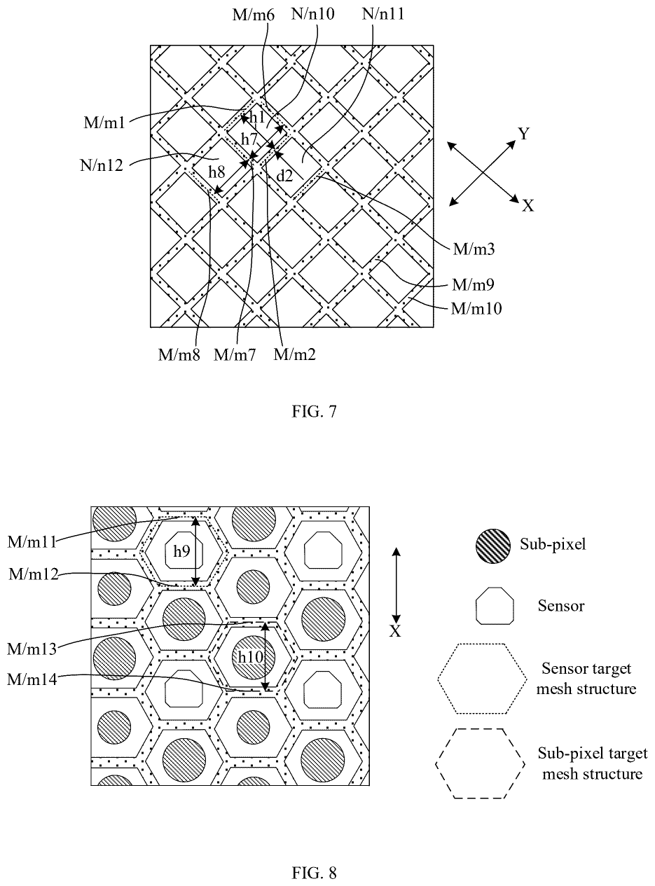

Referring to FIG. 6, any one of the first mesh structure groups A and the second mesh structure groups B is in a quadrilateral shape. The plurality of touch trace M also includes a sixth touch trace m6, a seventh touch trace m7, and an eighth touch trace m8 arranged in the second direction Y and adjacent to each other. The plurality of the first mesh structure groups A include at least a first target mesh structure group A1, and the plurality of the second mesh structure groups B include at least a second target mesh structure group B1 adjacent to the first target mesh structure group A1.

In some embodiments, the sixth touch trace m6 is a touch trace shared by the plurality of mesh structures N in the first target mesh structure group A1 on a side away from the second target mesh structure group B1. The seventh touch trace m7 is a touch trace shared by the plurality of mesh structures N in the first target mesh structure group A1 and the plurality of mesh structures N in the second target mesh structure group B1. The eighth touch trace m8 is a touch trace shared by the plurality of mesh structures N in the second target mesh structure group B1 on a side away from the first target mesh structure group A1.

A ratio of a seventh distance h7 between the sixth touch trace m6 and the seventh touch trace m7 in the second direction Y to an eighth distance h8 between the seventh touch trace m7 and the eighth touch trace m8 in the second direction Y ranges from 0.9 to 1.1. That is, in the embodiments, the touch traces arrayed in the second direction Y are also more uniformly arranged, which improves the touch uniformity of the touch panel 01.

In a third optional implementation, referring to FIG. 7, the plurality of touch traces M form a plurality of mesh structures N with each of the mesh structures being in a quadrilateral shape. The plurality of mesh structures N include at least a tenth target mesh structure n10 and an eleventh target mesh structure n11 arranged in the first direction X and adjacent to each other.

The first touch trace m1 is a touch trace of the tenth target mesh structure n10 away from the eleventh target mesh structure n11. The second touch trace m2 is a touch trace shared by the tenth target mesh structure n10 and the eleventh target mesh structure n11. The third touch trace m3 is a touch trace of the eleventh target mesh structure n11 away from the tenth target mesh structure n10.

That is, the width of the tenth target mesh structure n10 in the first direction X may be the first distance h1 between the first touch trace m1 and the second touch trace m2 in the first direction X. The width of the eleventh target mesh structure n11 in the first direction X may be the second distance h2 between the second touch trace m2 and the third touch trace m3 in the first direction X.

In the embodiments of the present disclosure, the plurality of touch traces M further includes a sixth touch trace m6, a seventh touch trace m7, and an eighth touch trace m8 that are arranged sequentially in the second direction Y and adjacent to each other.

A ratio of the seventh distance h7 between the sixth touch trace m6 and the seventh touch trace m7 in the second direction Y to the eighth distance h8 between the seventh touch trace m7 and the eighth touch trace m8 in the second direction Y ranges from 0.9 to 1.1. That is, the touch traces are arranged more uniformly in both the first direction X and the second direction Y, which can improve the uniformity of the field strength of the touch panel 01.

In some embodiments, the plurality of mesh structures N also includes a twelfth target mesh structure n12 adjacent to the tenth target mesh structure n10 in the second direction Y. The sixth touch trace m6 may be a touch trace of the tenth target mesh structure n10 away from the twelfth target mesh structure n12. The seventh touch trace m7 is a touch trace shared by the tenth target mesh structure n10 and the twelfth target mesh structure n12. The eighth touch trace m8 is a touch trace of the twelfth target mesh structure n12 away from the tenth target mesh structure n10.

That is, the width of the tenth target mesh structure n10 in the second direction Y may be the seventh distance h7 between the sixth touch trace m6 and the seventh touch trace m7 in the second direction Y. The width of the twelfth target mesh structure n12 in the second direction Y may be the eighth distance h8 between the seventh touch trace m7 and the eighth touch trace m8 in the second direction Y.

In the first implementation to the third implementation as described above, the plurality of touch trace M further includes a ninth touch trace m9 and a tenth touch trace m10 arranged in the first direction X and adjacent to each other.

The ninth touch trace m9 and the tenth touch trace m10 each is any one touch trace other than the second touch trace m2 in the plurality of touch traces M. Exemplarily, assuming that the ninth touch trace m9 is the first touch trace m1, the tenth touch trace m10 may be a touch trace on a side of the first touch trace ml away from the second touch trace m2 and adjacent to the first touch trace m1. Alternatively, assuming that the ninth touch trace m9 is the third touch trace m3, the tenth touch trace m10 may be a touch trace on a side of the third touch trace m3 away from the second touch trace m2 and adjacent to the third touch trace m3. Alternatively, assuming that the ninth touch trace m9 is any one touch trace other than the first touch trace m1, the second touch trace m2, and the third touch trace m3 in the plurality of touch traces M, the tenth touch trace m10 may be one of the two touch traces adjacent to the ninth touch trace m9.

In some embodiments, a ratio of a distance between the ninth touch trace m9 and the tenth touch trace m10 in the first direction X to the first distance h1 and a ratio of the distance between the ninth touch trace m9 and the tenth touch trace m 10 in the first direction X to the second distance h2 both range from 0.9 to 1.1. That is, in the embodiments of the present disclosure, in the plurality of touch traces M arrayed in the first direction X, the distance between any two of the touch traces that are adjacent to each other is approximately equal to the distance between the other two adjacent touch traces. That is, the plurality of touch traces M arranged in the first direction X are arranged more uniformly, and the uniformity of the field strength of the touch panel 01 is better, which in turn can improve the touch effect of the touch panel.

In the embodiment of the present disclosure, the display substrate 20 of the touch panel 01 may include a plurality of sensors in addition to the plurality of sub-pixels. Therefore, the plurality of mesh structures formed by the plurality of touch traces in the touch electrode structure 10 include a sub-pixel target mesh structure and a sensor target mesh structure. The sub-pixel target mesh structure surrounds a light-emitting region of at least one sub-pixel, and the sensor target mesh structure surrounds at least one sensor.

Referring to FIG. 8, the sub-pixel target mesh structure includes an eleventh touch trace m11 and a twelfth touch trace m 12 arrayed in the first direction X. The sensor target mesh structure includes a thirteenth touch trace m 13 and a fourteenth touch trace m 14 arrayed in the first direction.

A ratio of a ninth distance h9 between the eleventh touch trace m11 and the twelfth touch trace m12 in the first direction X to a tenth distance h10 between the thirteenth touch trace m13 and the fourteenth touch trace m14 in the first direction X ranges from 0.9 to 1.1.

That is, the distance of two touch traces arranged in the first direction X in the sub-pixel target mesh structure is approximately equal to the distance of two touch traces arranged in the first direction X in the sensor target mesh structure. The length of the sub-pixel target mesh structure in the first direction X is approximately equal to the length of the sensor target mesh structure in the first direction X. As a result, for the plurality of mesh structures formed by the plurality of touch traces, whether around the light-emitting region of the sub-pixel or around the sensor, the arrangement of the touch traces in the mesh structures is relatively uniform, which can lead to a better uniformity of the field strength of the touch panel 01.

In some embodiments, a ratio of the ninth distance h9 to the first distance h1 and a ratio of the ninth distance h9 to the second distance h2 both range from 0.9 to 1.1. A ratio of the tenth distance h10 to the first distance h1 and a ratio of the tenth distance h10 to the second distance h2 both range from 0.9 to 1.1.

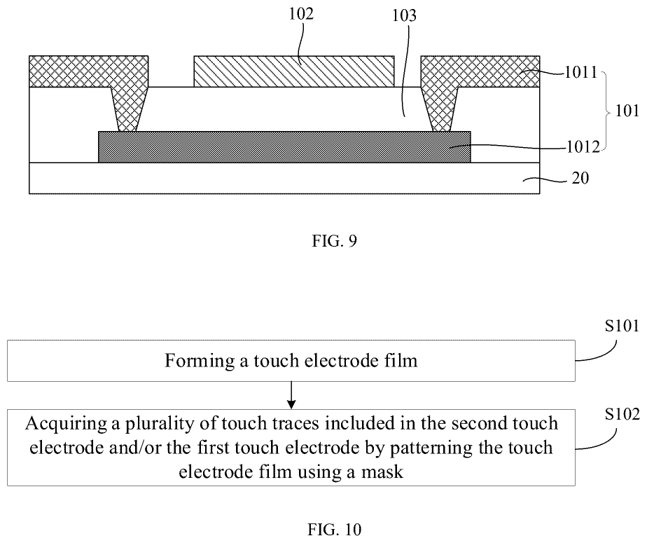

In the embodiments of the present disclosure, referring to FIG. 1, the touch electrode structure 10 also includes an insulating film layer 103. The first touch electrode 101 and the second touch electrode 102 may be disposed on both sides of the insulating film layer 103. Alternatively, referring to FIG. 9, the first touch electrode 101 includes a main electrode 1011 and a bridging electrode 1012, the main electrode 1011 and the second touch electrode 102 are disposed on one side of the insulating film layer 103, the bridging electrode 1012 is disposed on the other side of the insulating film layer 103, and the bridging electrode 1012 and the main electrode 1011 are connected through a via in the insulating film layer 103.

In summary, the embodiments of the present disclosure provide a touch electrode structure. In a plurality of touch traces included in a first touch electrode and in a second touch electrode that are insulated from each other in the touch electrode structure, a ratio of a first distance between a first touch trace and a second touch trace in a first direction to a second distance between the second touch trace and a third touch trace in a second direction is close to 1. That is, the first touch trace, the second touch trace, and the third touch trace that are arranged in the first direction and adjacent to each other are arranged more uniformly, which can improve the uniformity of the field strength of the touch panel, improve the uniformity and sensitivity of the capacitive sensing signal of the touch panel, thereby improving the touch effect of the touch panel, and avoiding visibility problems of the display device simultaneously.

FIG. 10 is a flowchart of a method for preparing a touch electrode structure according to some embodiments of the present disclosure. Referring to FIG. 10, the method includes the following steps.

In step S101, a touch electrode film is formed.

In the embodiments of the present disclosure, a conductive material may be used to form the touch electrode film. The conductive material may be a metallic material, and the touch electrode film may be a whole film.

In step S102, a plurality of touch traces included in the second touch electrode and/or the first touch electrode are acquired by patterning the touch electrode film using a mask.

In the embodiments of the present disclosure, the process of patterning includes photoresist coating, exposing the photoresist using a mask, developing, etching, and removing the photoresist.

In a possible case, in the case that the touch electrode structure is the structure shown in FIG. 1, the touch electrode film formed by step S101 above may be a first film for forming the first touch electrode 101. In step S102, a plurality of touch traces M included in the first touch electrode 101 may be acquired after the first film is patterned using a first mask; an insulating film layer may be formed on a side of the first touch electrode 101 to insulate the first touch electrode 101 and the second touch electrode 102 formed thereafter; then after, by re-executing the above step S101, a touch electrode film (a second film for forming the second touch electrode 102) is formed on a side of the insulating film layer away from the first touch electrode 101; and re-executing the step S102, a plurality of touch traces M included in the second touch electrode 102 may be acquired after the second film is patterned using a second mask.

That is, in this implementation, the plurality of touch traces M included in the first touch electrode 101 and the plurality of touch traces M included in the second touch electrode 102 may be prepared in batches.

In another possible case, in the case that the touch electrode structure is the structure shown in FIG. 9, the touch electrode film formed in step S101 above may be a first film for forming the bridging electrode of the first touch electrode 101. In step S102, a plurality of touch traces M included in the bridging electrode 1012 of the first touch electrode 101 may be acquired after the first film is patterned using a first mask; an insulating film layer is formed on a side of the bridging electrode 1012 of the first touch electrode 101; by re-executing the above step S101, the touch electrode film may be formed on a side of the insulating film layer away from the bridging electrode 1012 (a second film for forming the main electrode of the first touch electrode 101 and the second touch electrode 102); and by re-executing step S102, a plurality of touch traces M included in the main electrode of the first touch electrode 101 and a plurality of touch traces M included in the second touch electrode 102 may be acquired after the second film is patterned using a second mask.

That is, in this implementation, the plurality of touch traces M included in the bridging electrode in the first touch electrode 101 may be prepared first, and then the plurality of touch traces M included in the main electrode of the first touch electrode 101 and the plurality of touch traces M included in the second touch electrode 102 may be prepared.

It is to be noted that, regardless of the structure shown in FIG. 1 or the structure shown in FIG. 9 above, the plurality of touch traces M disposed in the same layer and belonging to the same touch electrode include at least the first touch traces m1, the second touch traces m2, and the third touch traces m3 arranged sequentially in the first direction X and adjacent to each other.

A ratio of a first distance h1 between the first touch trace ml and the second touch trace m2 in the first direction X to a second distance h2 between the second touch trace m2 and the third touch trace m3 in the first direction X ranges from 0.9 to 1.1. That is, the ratio of the first distance h1 of the first touch trace m1 and the second touch trace m2 in the first direction X to the second distance h2 of the second touch trace m2 and the third touch trace m3 in the first direction X is close to 1, and the first distance h1 is approximately equal to the second distance h2.

The first direction X may be an arrangement direction of the plurality of sub-pixels that are arranged in an array and being of the display substrate in the touch panel. For example, the first direction X may be a column direction of the sub-pixels or a row direction of the sub-pixels.

Since the first distance h1 between the first touch trace m1 and the second touch trace m2 in the first direction X and the second distance h2 between the second touch trace m2 and the third touch trace m3 in the first direction X are approximately equal, the first touch trace m1, the second touch trace m2, and the third touch trace m3 can be arranged more uniformly, which improves the uniformity of the field strength of the touch panel, and thus improves the uniformity and sensitivity of the capacitive sensing signal of the touch panel. In this way, the touch effect of the touch panel can be improved, and visibility problems of the display device can be avoided simultaneously.

In summary, the embodiments of the present disclosure provide a method for preparing a touch electrode structure. In a plurality of touch traces included in a first touch electrode and in a second touch electrode that are insulated from each other in the touch electrode structure prepared by this method, a ratio of a first distance between a first touch trace and a second touch trace in a first direction to a second distance between the second touch trace and a third touch trace in a second direction is close to 1. That is, the first touch trace, the second touch trace, and the third touch trace that are arranged in the first direction and adjacent to each other are arranged more uniformly, which can improve the uniformity of the field strength of the touch panel, improve the uniformity and sensitivity of the capacitive sensing signal of the touch panel, thereby improving the touch effect of the touch panel, and avoiding visibility problems of the display device simultaneously.

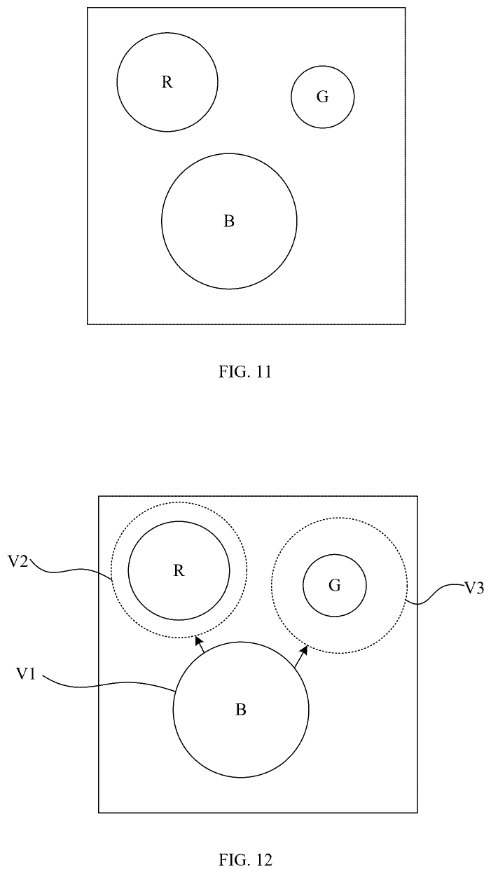

In the embodiments of the present disclosure, referring to FIG. 11, a plurality of sub-pixels of the display substrate in the touch panel 01 form a plurality of pixels. Each pixel includes at least one first color sub-pixel, one second color sub-pixel, and one third color sub-pixel. The first color may be blue (B), the second color may be red (R) and the third color may be green (G). FIG. 11 shows one blue sub-pixel B, one red sub-pixel R, and a green sub-pixel G. The light-emitting region of each sub-pixel is in a circular shape, with the area of the light-emitting region of the blue sub-pixel B, the area of the light-emitting region of the red sub-pixel R, and the area of the light-emitting region of the green sub-pixel G decreasing in order.

The plurality of touch traces included in either the first touch electrode 101 or the second touch electrode 102 may be prepared using a mask. The mask may be provided with openings for forming the plurality of touch traces. In the embodiment of the present disclosure, the design process of a target opening in the plurality of openings includes the following steps.

In step 1, referring to FIG. 12, a center of a first dummy reference pattern V1 is positioned to overlap with a center of a light-emitting region of the first color sub-pixel, a center of a second dummy reference pattern V2 is positioned to overlap with a center of a light-emitting region of the second color sub-pixel, and a center of a third dummy reference pattern V3 is positioned to overlap with a center of a light-emitting region of the third color sub-pixel.

The first dummy reference pattern V1, the second dummy reference pattern V2, and the third dummy reference pattern V3 all have the same shape and size, and are only provided at different positions.

In the embodiments of the present disclosure, the shape and size of each of the dummy reference patterns are determined based on the shape and size of the light-emitting region of each of the first color sub-pixel, the second color sub-pixel, and the third color sub-pixel. Exemplarily, in the case that the shape of each sub-pixel is the same, the dummy reference pattern may be determined based on the light-emitting region with the largest area in the sub-pixels. Alternatively, regardless of whether the shape of each sub-pixel is the same, the length of the dummy reference pattern may be determined based on the length of the light-emitting region having the longest length among the sub-pixels. At the same time, the dummy reference pattern also needs to satisfy that the center of the dummy reference pattern and the center of the light-emitting region of the sub-pixel overlap to cover the light-emitting region.

In step 2, a target opening is designed in a region, of the mask, disposed between the first target reference pattern and the second target reference pattern, and a distance between the target opening and the first target reference pattern is equal to a distance between the target opening and the second target reference pattern.

The first target reference pattern and the second target reference pattern are two adjacent reference patterns in the first dummy reference pattern, the second dummy reference pattern, and the third dummy reference pattern.

Since the distance between the target opening of the mask and the first target reference pattern is equal to the distance between the target opening and the second target reference pattern, a distance between the touch trace prepared by the target opening of the mask and the first target reference pattern is equal to the distance between the touch trace and the second target reference pattern. Further, for the dummy reference pattern corresponding to each sub-pixel in the embodiments of the present disclosure, an opening is designed between any two adjacent dummy reference patterns, which is equal in distance to the two dummy reference patterns on both sides.

In the solution of the related art, assuming that the first color sub-pixel and the second color sub-pixel are adjacent to each other, and the touch trace needs to be designed between the first color sub-pixel and the second color sub-pixel, the target opening of the mask herein may be designed, so that the distance between the target opening and the light-emitting region of the first sub-pixel is equal to the distance between the target opening and the light-emitting region of the second color sub-pixel. The disadvantage of this solution is that, due to differences in the shapes and sizes of the light-emitting regions of the different sub-pixels, the arrangement of the openings in the mask designed by this method is not uniformly designed, which in turn may lead to an uneven arrangement of the plurality of touch traces obtained by the preparation of the mask, which may affect the uniformity of the field strength of the touch panel.

Whereas, in the solution of the embodiments of the present disclosure, a dummy reference pattern corresponding to each sub-pixel is first pre-determined, and the shapes and sizes of the dummy reference patterns corresponding to different sub-pixels are the same. Designing a target opening of the mask based on the two identical dummy reference patterns can ensure that the distance between the touch trace formed by the target opening and the two dummy reference patterns is equal. Further, the plurality of openings in the mask are designed by this method, such that the arrangement of the plurality of touch traces M prepared by the mask can be more uniform, and the uniformity of the field strength of the touch panel can be improved.

In the embodiments of the present disclosure, referring to FIG. 18, the plurality of sub-pixels included in the display substrate in the touch panel 01 form a plurality of pixels. Each pixel includes at least one blue sub-pixel, one red sub-pixel, and one green sub-pixel.

In addition, the display substrate also includes a plurality of sensors S. Therefore, when selecting a dummy reference pattern, the shape and size of the sensor S need to be considered. Typically, the shape of the sensor S is different from the shape of the light-emitting region of each sub-pixel. However, since the area of the sensor S is usually smaller than the size of the largest light-emitting region in the plurality of sub-pixels, a dummy reference pattern selected based on the light-emitting regions of the plurality of sub-pixels can satisfy the requirement that the dummy reference pattern covers the sensor S in the case that a center of the dummy reference pattern overlaps a center of the sensor S. As a result, whether or not the touch panel includes the sensor S, the dummy reference pattern can be determined based on the light-emitting regions of the plurality of sub-pixels in the touch panel 01.

That is, for the embodiments shown in FIG. 13, the design process of a target opening in the plurality of openings of the mask includes the following steps.

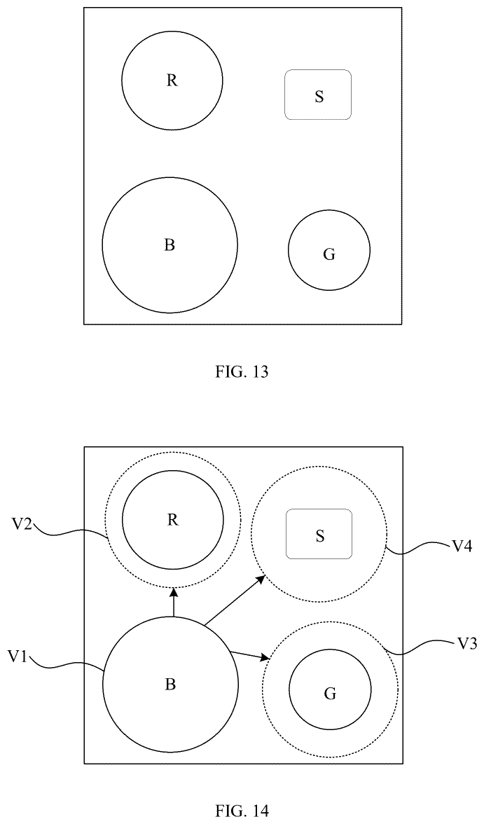

In step 1, referring to FIG. 14, a center of a first dummy reference pattern V1 is positioned to overlap with a center of a light-emitting region of the first color sub-pixel, a center of a second dummy reference pattern V2 is positioned to overlap with a center of a light-emitting region of the second color sub-pixel, a center of a third dummy reference pattern V3 is positioned to overlap with a center of a light-emitting region of the third color sub-pixel, and a center of a fourth dummy reference pattern V4 is positioned to overlap with a center of a light-emitting region of a sensor.

The first dummy reference pattern V1, the second dummy reference pattern V2, the third dummy reference pattern V3, and the fourth dummy reference pattern V4 have the same shape and size, and are only provided at different positions.

In the embodiments of the present disclosure, the shape and size of each of the dummy reference patterns are determined based on the shape and size of the light-emitting region of each of the first color sub-pixel, the second color sub-pixel, and the third color sub-pixel. Exemplarily, in the case that the shape of each sub-pixel is the same, the dummy reference pattern may be determined based on the light-emitting region with the largest area in the sub-pixels. Alternatively, regardless of whether the shape of each sub-pixel is the same, the length of the dummy reference pattern may be determined based on the length of the light-emitting region having the longest length among the sub-pixels. At the same time, the dummy reference pattern also needs to satisfy that the center of the dummy reference pattern and the center of the light-emitting region of the sub-pixel or the sensor overlap to cover the light-emitting region or the sensor.

In step 2, a target opening is designed in a region, of the mask, disposed between the first target reference pattern and the second target reference pattern, and a distance between the target opening and the first target reference pattern is equal to a distance between the target opening and the second target reference pattern.

The first target reference pattern and the second target reference pattern are two adjacent reference patterns in the first dummy reference pattern, the second dummy reference pattern, the third dummy reference pattern, and the fourth dummy reference pattern.

Since the distance between the target opening of the mask and the first target reference pattern is equal to the distance between the target opening and the second target reference pattern, a distance between the touch trace prepared by the target opening of the mask and the first target reference pattern is equal to the distance between the touch trace and the second target reference pattern. Further, an opening is designed between any two adjacent dummy reference patterns in the embodiments of the present disclosure, which is equal in distance to the two dummy reference patterns on both sides.

In the solution of the embodiments of the present disclosure, a dummy reference pattern corresponding to each sub-pixel and each sensor is first pre-determined, and the shapes and sizes of the dummy reference patterns corresponding to different sub-pixels and sensors are the same. Designing a target opening of the mask based on the two identical dummy reference patterns can ensure that the distance between the touch trace formed by the target opening and the two dummy reference patterns is equal. Further, the plurality of openings in the mask are designed by this method, such that the arrangement of the plurality of touch traces M prepared by the mask can be more uniform, and the uniformity of the field strength of the touch panel can be improved.

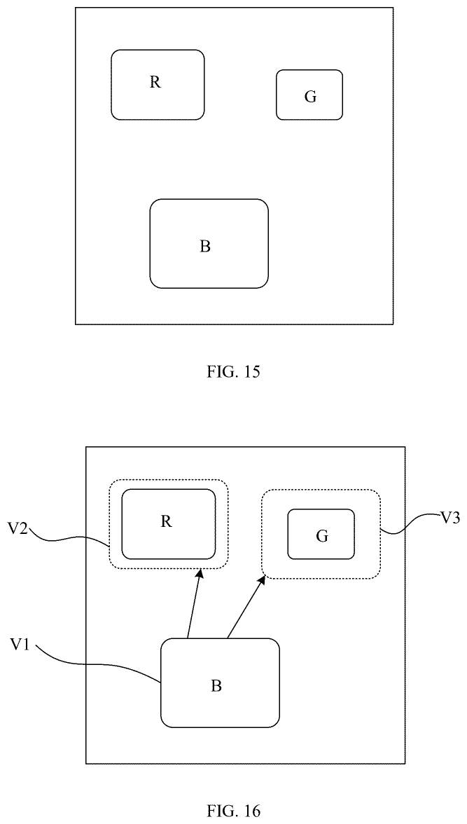

In a first possible case, referring to FIG. 11, FIG. 13, and FIG. 15, each pixel includes one blue sub-pixel B, one red sub-pixel R, and one green sub-pixel G. The shape of the light-emitting region of the blue sub-pixel B, the shape of the light-emitting region of the red sub-pixel R, and the shape of the light-emitting region of the green sub-pixel G are the same. The area of the light-emitting region of the blue sub-pixel B, the area of the light-emitting region of the red sub-pixel R, and the area of the light-emitting region of the green sub-pixel G are reduced in turn. That is, the area of the light-emitting region of the blue sub-pixel B is larger than the area of the light-emitting region of the red sub-pixel R, and the area of the light-emitting region of the red sub-pixel R is larger than the area of the light-emitting region of the green sub-pixel G.

The shape of the light-emitting region of the blue sub-pixel B, the shape of the light-emitting region of the red sub-pixel R, and the shape of the light-emitting region of the green sub-pixel G are the same may mean that the shape of the light-emitting region of the blue sub-pixel B, the shape of the light-emitting region of the red sub-pixel R, and the shape of the light-emitting region of the green sub-pixel G are the same or substantially the same.

Exemplarily, referring to FIG. 11 and FIG. 13, the shape of the light-emitting region of the blue sub-pixel B, the shape of the light-emitting region of the red sub-pixel R, and the shape of the light-emitting region of the green sub-pixel G are circular, in which case the shapes of the light-emitting regions of the three sub-pixels are identical. Alternatively, referring to FIG. 15, the shape of the light-emitting region of the blue sub-pixel B, the shape of the light-emitting region of the red sub-pixel R, and the shape of the light-emitting region of the green sub-pixel G are all quadrilateral shapes with rounded chamfers at the corners, and the size of the rounded chamfers may be different, in which case the shapes of the light-emitting regions of the three sub-pixels are approximately the same.

In this case, the shape of each dummy reference pattern may be the same as the shape of the light-emitting region of each sub-pixel. Moreover, the area of each dummy reference pattern may be greater than or equal to the area of the light-emitting region with the largest area among the light-emitting regions of the three sub-pixels. For example, the area of each dummy reference pattern is greater than or equal to the area of the light-emitting region of the blue sub-pixel B.

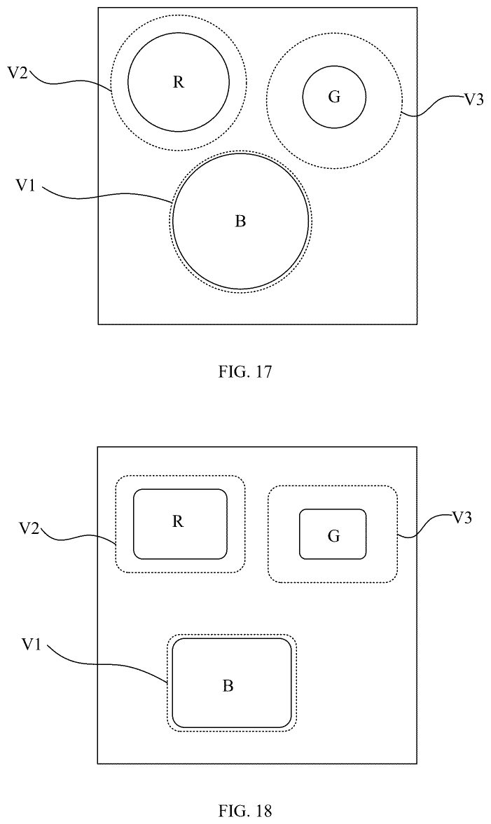

Exemplarily, referring to FIG. 12 and FIG. 16, the pattern of the light-emitting region of the blue sub-pixel B may be directly used as the dummy reference patterns (V1, V2, and V3) to design the openings of the mask. Alternatively, referring to FIG. 17 and FIG. 18, the openings of the mask may be designed by appropriately increasing a certain size based on the pattern of the light-emitting region of the blue sub-pixel B to serve as the dummy reference patterns (V1, V2, and V3).

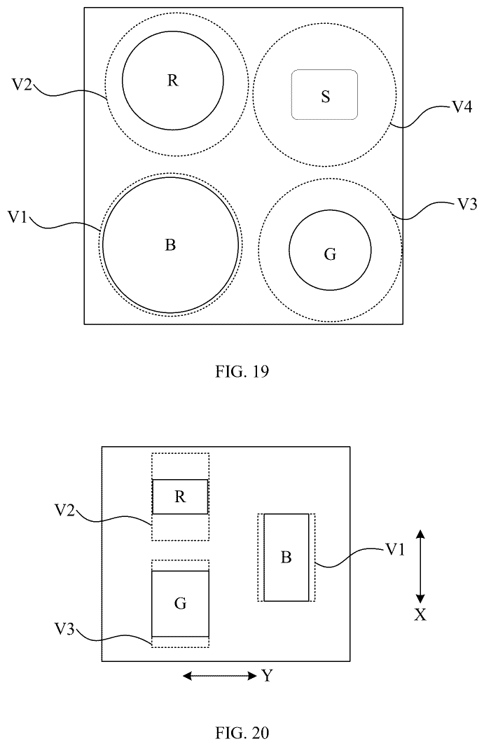

Referring to FIG. 13, the openings of the mask may be designed by directly using the pattern of the light-emitting region of the blue sub-pixel B as the dummy reference patterns (V1, V2, V3, and V4). Alternatively, referring to FIG. 19, the openings of the mask may be designed by appropriately increasing a certain size based on the pattern of the light-emitting region of the blue sub-pixel B to serve as the dummy reference patterns (V1, V2, V3, and V4).

In a second possible case, regardless of whether the shapes of the light-emitting regions of the color sub-pixels are the same, the lengths of the two directions may be selected as a reference, and the dimensions of the dummy reference patterns may be determined based on the dimensions of the lengths that are the longest of the two directions.

In some embodiments, the length of each dummy reference pattern in the first direction X is greater than or equal to the longest length among the length of the light-emitting region of the blue sub-pixel B in the first direction X, the length of the light-emitting region of the red sub-pixel R in the first direction X, and the length of the light-emitting region of the green sub-pixel G in the first direction X. The length of each dummy reference pattern in the second direction Y is greater than or equal to the longest length among the length of the light-emitting region of the blue sub-pixel B in the second direction Y, the length of the light-emitting region of the red sub-pixel R in the second direction Y, and the length of the light-emitting region of the green sub-pixel G in the second direction Y. The second direction Y is perpendicular to the first direction X. Moreover, the shape of the dummy reference pattern is the same as the shape of at least one of the light-emitting region of the blue sub-pixel B, the light-emitting region of the red sub-pixel R, or the light-emitting region of the green sub-pixel G.

Referring to FIG. 20, assuming that in the three color sub-pixels, the light-emitting region of the blue sub-pixel B has the longest length in the first direction X, and the light-emitting region of the green sub-pixel G has the longest length in the second direction Y. As a result, it is possible to design the lengths of the dummy reference patterns (V1, V2, and V3) in the first direction X to be greater than or equal to the length of the light-emitting region of the blue sub-pixel B in the first direction X and to design the lengths of the dummy reference patterns (V1, V2, and V3) in the second direction Y to be greater than or equal to the length of the light-emitting region of the green sub-pixel G in the second direction Y.

In a third possible case, each pixel includes one blue sub-pixel B, one red sub-pixel R, and two green sub-pixels G. In addition, a distance between the light-emitting regions of the two green sub-pixels G is less than 14 micrometers (um), i.e., the distance between the light-emitting regions of the two green sub-pixels G is small, and the light-emitting region of the two green sub-pixels G may be considered to be designed as a single object opening of the mask, i.e., the light-emitting regions of the two green sub-pixels G share one dummy reference pattern.

In some embodiments, the length of each dummy reference pattern (V1, V2, and V3) in the first direction X is a first target length. The first target length is greater than or equal to the longest length among the length of the light-emitting region of the blue sub-pixel B in the first direction X, the length of the light-emitting region of the red sub-pixel R in the first direction X, and the length of the target pattern in the first direction X. The length of each dummy reference pattern (V1, V2 and V3) in the second direction Y is a second target length. The second target length is greater than or equal to the longest length among the length of the light-emitting region of the blue sub-pixel B in the second direction Y, the length of the light-emitting region of the red sub-pixel R in the second direction Y, and the length of the target pattern in the second direction Y.

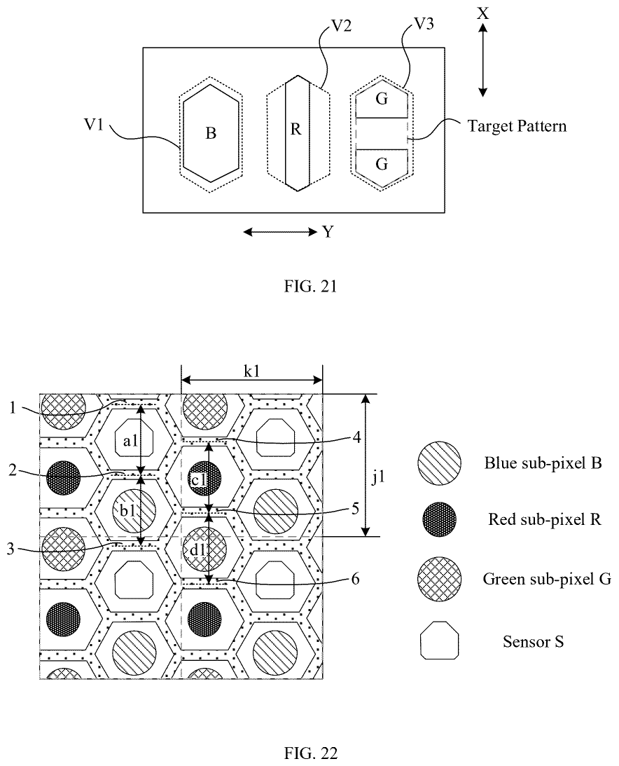

Referring to FIG. 21, the target pattern is a minimum external pattern of the light-emitting regions of the two green sub-pixels G. The shape of the minimum external pattern is the same as the shape of the light-emitting region of the blue sub-pixel B, and/or, the shape of the minimum external pattern is the same as the shape of the light-emitting region of the red sub-pixel R. The dummy reference pattern (V1, V2, and V3) has the same shape as at least one of the light-emitting region of the blue sub-pixel B, the light-emitting region of the red sub-pixel R, or the target pattern.

In the embodiments of the present disclosure, the shapes and sizes of the dummy reference patterns can be determined in combination with the above three possible cases, and then the openings in the mask can be designed based on the determined dummy reference patterns. Typically, the arrangement of the plurality of sub-pixels of the display substrate in the touch panel includes: 1. RGB+sensor; 2. Real RGB; 3. GGRB; and 4. circular GGRB.

Referring to FIG. 22, taking the arrangement of the plurality of sub-pixels of the display substrate being RGB+sensor as an example. In this implementation, each pixel includes one blue sub-pixel B, one red sub-pixel R, and one green sub-pixel G. In FIG. 22, the area of the light-emitting region of the green sub-pixel G is larger than the area of the light-emitting region of the blue sub-pixel B, and the area of the light-emitting region of the blue sub-pixel B is larger than the area of the light-emitting region of the red sub-pixel R. Moreover, the shapes of the light-emitting regions of the three different color sub-pixels are all circular. The touch panel also includes a plurality of sensors S, and each of the sensors S is in a non-circular shape.

For the mask for preparing the touch electrode structure corresponding to the display substrate shown in FIG. 22, the design of the openings in the mask may satisfy that the shapes and sizes of the dummy reference patterns are determined based on the light-emitting regions of the blue sub-pixel B, the light-emitting regions of the red sub-pixel R, and the light-emitting regions of the green sub-pixel G, and then the centers of the various dummy reference patterns overlap with the centers of the respective sub-pixels or the centers of the sensors, so as to design an opening of the mask thereof at the middle position of two adjacent dummy reference patterns.

In a first embodiment, a pattern of the light-emitting region of the green sub-pixel G is selected as a dummy reference pattern (respective dummy reference patterns are not shown in the drawings). A center of a first dummy reference pattern is positioned to overlap with a center of the light-emitting region of the blue sub-pixel B, a center of a second dummy reference pattern is positioned to overlap with a center of the light-emitting region of the red sub-pixel R, a center of a third dummy reference pattern is positioned to overlap with a center of the light-emitting region of the green sub-pixel G, and a center of a fourth dummy reference pattern is positioned to overlap with a center of the sensor S.

FIG. 22 shows four columns of sub-pixels, with two columns of sensors S and blue sub-pixels B being staggered, and the other two columns of red sub-pixels R and green sub-pixels G being staggered. In addition, the columns of pixels with different sub-pixel arrangements are staggered. For an opening formed between the sensor S and the blue sub-pixel B in the mask, a distance between the opening and the fourth dummy reference pattern is equal to a distance between the opening and the first dummy reference pattern. For an opening formed between the red sub-pixel R and the green sub-pixel G in the mask, a distance between the opening and the second dummy reference pattern is equal to a distance between the opening and the third dummy reference pattern. That is, for an opening of a touch trace formed between any two adjacent sub-pixels in the mask, the opening is provided at a midline position of two adjacent dummy reference patterns.

In the touch electrode structure prepared by the mask designed by the design method provided by the embodiments of the present disclosure, the distance detection results in that a distance al between a touch trace 1 and a touch trace 2 and a distance b1 between the touch trace 2 and a touch trace 3 are equal to 39 um, a distance cl between a touch trace 4 and a touch trace 5 and a distance d1 between the touch trace 5 and a touch trace 6 are equal to 39 μm, and the distance c1 between the touch trace 4 and the touch trace 5 and the distance dl between the touch trace 5 and the touch trace 6 are equal to 39 μm. i.e., a1=b1=39 μm, and c1=d1=39 μm, with a1:b1=1 and c1:d1=1. Moreover, in FIG. 22, the box with length k1 and width j1 is the smallest repeating unit containing a set of RGB pixels and a sensor, with k1=78 μm, and j1=78 μm. a1+b1=k1, c1+d1=j1.

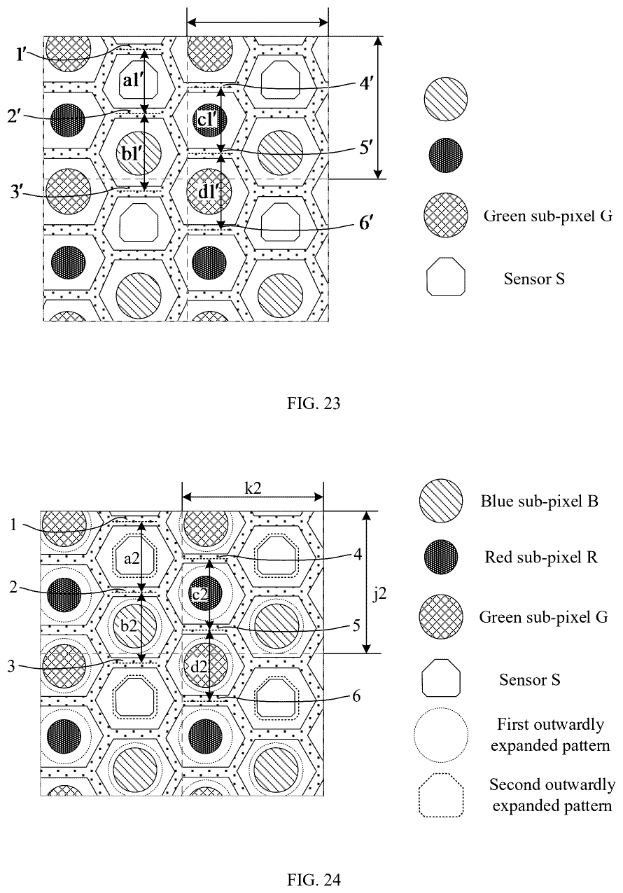

Referring to the related art of FIG. 23, a distance between a touch trace 2′ and the light-emitting region of the blue sub-pixel B is equal to a distance between the touch trace 2′ and the sensor S. A distance between the touch trace 5′ and the light-emitting region of the red sub-pixel R is equal to a distance between the touch trace 5′ and the light-emitting region of the green sub-pixel G. That is, the touch trace is provided at a midline position of the light-emitting regions of two adjacent sub-pixels, or a midline position of the light-emitting regions of the sub-pixel and the sensor.

In the solution of the related art, the distance detection results in that a distance a1′ between the touch trace l′ and the touch trace 2′ is 34.865 μm, and a distance b1′ between the touch trace 2′ and the touch trace 3′ is 43.135 μm. A distance c1′ between the touch trace 4′ and the touch trace 5′ is 36.09 μm, and a distance d1′ between the touch trace 5′ and the touch trace 6′ is 41.91 μm. That is, a1′:b1′=0.81, c1′:d1′=0.86. a1′+b1′=n1, c1′+d1′=n1.

Combined with the ratio of the distance between the touch traces in the embodiments of the present disclosure and the ratio of the distance between the touch traces in the related art, the ratio of the distance between the touch traces in the embodiments of the present disclosure is improved by 19% for a1:b1 with respect to a1′:b1′, and improved by 14% for c1:d1 with respect to c1′:d1′. As a result, the uniformity of the touch trace in the embodiments of the present disclosure is improved by at least 14% with respect to the related art.

In a second embodiment, taking into account the optical effect of the light-emitting region of each sub-pixel in the display substrate, and avoiding that the touch trace affects the light emission from the light-emitting region, a dummy reference pattern may be determined based on a first outwardly expanded pattern of the light-emitting region of the green sub-pixel G, and a second outwardly expanded pattern of the sensor S. Referring to FIG. 24, a center of the first dummy reference pattern is positioned to overlap with a center of the light-emitting region of the blue sub-pixel B, a center of the second dummy reference pattern is positioned to overlap with a center of the light-emitting region of the red sub-pixel R, a center of the third dummy reference pattern is positioned to overlap with a center of the light-emitting region of the green sub-pixel G, and a center of the fourth dummy reference pattern is positioned to overlap with a center of the sensor S.

FIG. 24 shows four columns of sub-pixels, with two columns of the sensors S and the blue sub-pixel B being staggered, and the other two columns of the red sub-pixel R and the green sub-pixel G being staggered. In addition, the columns of pixels with different sub-pixel arrangements are staggered. For an opening formed between the sensor S and the blue sub-pixel B in the mask, a distance between the opening and the fourth dummy reference pattern is equal to a distance between the opening and the first dummy reference pattern. For an opening formed between the red sub-pixel R and the green sub-pixel G in the mask, a distance between the opening and the second dummy reference pattern is equal to a distance between the opening and the third dummy reference pattern. That is, for an opening of a touch trace formed between any two adjacent sub-pixels in the mask, the opening is provided at a midline position of two adjacent dummy reference patterns.

The position of the openings can be fine-tuned after the above distance-equal design. In the touch trace prepared by the mask designed by the design method provided by the embodiments of the present disclosure, the distance detection results in that a distance a2 between the touch trace 1 and the touch trace 2 is 37.7 μm, a distance b2 between the touch trace 2 and the touch trace 3 is 40.3 μm. A distance c2 between the touch trace 4 and the touch trace 5 is 37.7 μm, and a distance d2 between touch trace 5 and touch trace 6 is 40.3 μm. i.e., a2:b2=0.94, c2:d2=0.94. Moreover, in FIG. 24, the box with length k2 and width j2 is the smallest repeating unit containing a set of RGB pixels and a sensor, k2=78 μm, j2=78 μm. a2+b2−j2, c2+d2=j2.

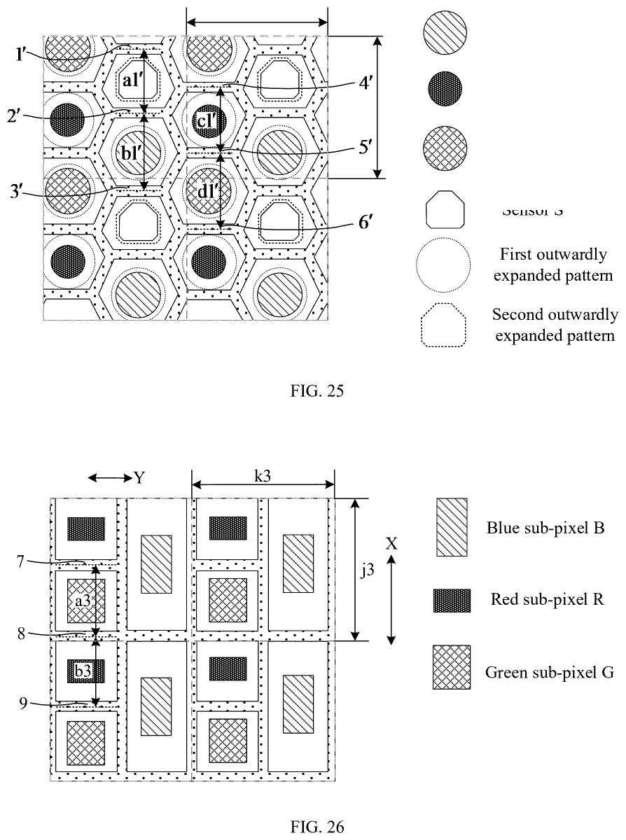

Referring to the related art of FIG. 25, a distance between the touch trace 2′ and a first outwardly expanded pattern at the light-emitting region of the blue sub-pixel is equal to a distance between the touch trace 2′ and a second outwardly expanded pattern at the sensor. A distance between the touch trace 5′ and a first outwardly expanded pattern at the light-emitting region of the red sub-pixel is equal to the distance between a touch trace and a first outwardly expanded pattern at the light-emitting region of the green sub-pixel. That is, the touch trace is provided at a midline position of two adjacent first outwardly expanded patterns, or at a midline position of a first outwardly expanded pattern and a second outwardly expanded pattern that are adjacent.

In the solution of the related art, the distance detection results in that a distance a2′ between the touch trace 1′ and the touch trace 2′ is 34.865 μm, and a distance b2′ between the touch trace 2′ and the touch trace 3′ is 43.135 μm. A distance c2′ between the touch trace 4′ and the touch trace 5′ is 36.09 μm, and a distance d2′ between the touch trace 5′ and the touch trace 6′ is 41.91 μm. That is, a2′:b2′=0.81, c2′:d2′=0.86. a2′+b2′=j2, c2′+d2′=j2.

Combined with the ratio of the distance between the touch traces in the embodiments of the present disclosure and the ratio of the distance between the touch traces in the related art, the ratio of the distance between the touch traces in the embodiments of the present disclosure is improved by 13% for a2:b2 with respect to a2′:b2′, and improved by 8% for c2:d2 with respect to c2′:d2′. As a result, the uniformity of the touch trace in the embodiment of the present disclosure is improved by at least 8% with respect to the related art.

In a third embodiment, referring to FIG. 26, the arrangement of the plurality of sub-pixels of the display substrate is Real RGB as an example. In this implementation, each pixel includes one blue sub-pixel B, one red sub-pixel R, and one green sub-pixel G. The green sub-pixel G is a green sub-pixel.

In FIG. 26, the length of the light-emitting region of the green sub-pixel G in the second direction Y is the longest length among the lengths of the light-emitting regions of the three sub-pixels in the second direction Y. The length of the light-emitting region of the blue sub-pixel B in the first direction X is the longest length among the lengths of the light-emitting regions of the three sub-pixels in the first direction X.

For a mask for preparing a touch electrode structure corresponding to the display substrate shown in FIG. 26, the design process of an opening in the mask is as follows: the length of the light-emitting region of the green sub-pixel G in the second direction Y serves as the length of the dummy reference pattern in the second direction Y, and the length of the light-emitting region of the blue sub-pixel B in the first direction X serves as the length of the dummy reference pattern in the first direction X. Further, the centers of the respective dummy reference patterns overlap with the centers of the light-emitting regions of the respective sub-pixels, so as to design an opening of the mask thereof at the middle position of two adjacent dummy reference patterns.

In some embodiments, the center of the first dummy reference pattern is positioned to overlap with the center of the light-emitting region of the blue sub-pixel B, the center of the second dummy reference pattern is positioned to overlap with the center of the light-emitting region of the red sub-pixel R, and the center of the third dummy reference pattern is positioned to overlap with the center of the light-emitting region of the green sub-pixel G.

Referring to FIG. 26, four columns of sub-pixels are shown, with two columns of the red sub-pixels R and green sub-pixels G being staggered and the other two columns of the blue sub-pixels B being arranged sequentially. In addition, the columns of pixels with different sub-pixel arrangements are staggered. For an opening formed between the red sub-pixel R and the green sub-pixel G in the mask, a distance between the opening and the second dummy reference pattern is equal to a distance between the opening and the third dummy reference pattern. For an opening formed between two adjacent blue sub-pixels B in the mask, a distance between the opening and one of the two adjacent first dummy reference patterns is equal to a distance between the opening and the other of the two adjacent first dummy reference patterns. That is, for an opening of a touch trace formed between any two adjacent sub-pixels in the mask, the opening is provided at a midline position of two adjacent dummy reference patterns.

In the touch electrode structure prepared by the mask designed by the design method provided by the embodiments of the present disclosure, the distance detection results in that a distance a3 between the touch trace 7 and the touch trace 8 and a distance b3 between the touch trace 8 and the touch trace 9 are all 38.25 μm. i.e., a3=b3=38.25 μm, and a3:b3=1. Moreover, in FIG. 26, the box with length k3 and width j3 is the smallest repeating unit containing a set of RGB pixels, with k3=76.5 μm and j3=76.5 μm. a3+b3=j3.

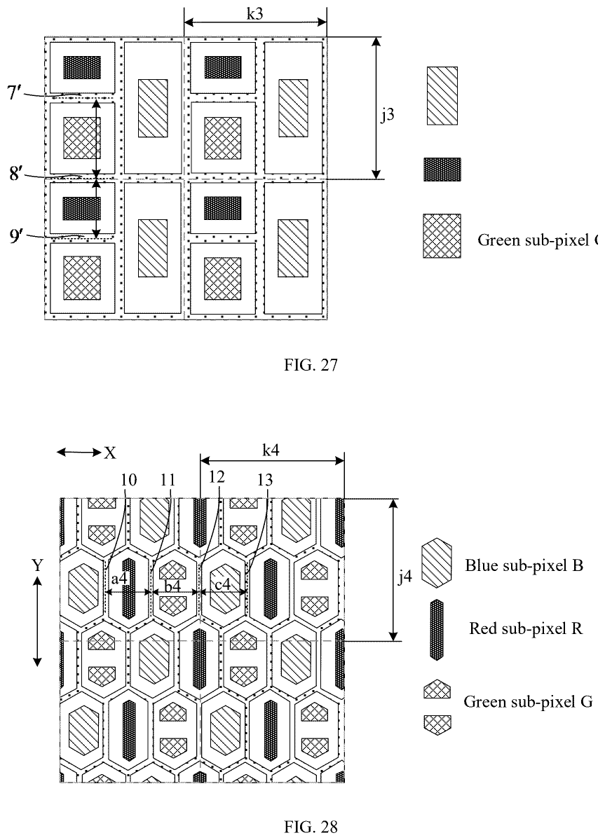

Referring to the related art of FIG. 27, a distance between the touch trace 8′ and the light-emitting region of the red sub-pixel R is equal to a distance between the touch trace 8′ and the light-emitting region of the green sub-pixel G. A distance between the touch trace 8′ and the light-emitting region of one of two adjacent blue sub-pixels B and a distance between the touch trace 8′ and the light-emitting region of the other of the two adjacent blue sub-pixels B is equal. That is, the touch trace is provided at a midline position of the light-emitting regions of two adjacent sub-pixels.

In the solution of the related art, the distance detection results in that a distance a3′ between the touch trace 7′ and the touch trace 8′ is 43.75 μm, and a distance b3′ between the touch trace 8′ and the touch trace 9′ is 32.75 μm. i.e., a3′:b3′=1.36, a3′+b3′=j3.

Combined with the ratio of the distance between the touch traces in the embodiments of the present disclosure and the ratio of the distance between the touch traces in the related art, the ratio of the distance between the touch traces in the embodiments of the present disclosure is reduced by 36% for a3:b3 with respect to a3′:b3′. As a result, the uniformity of the touch trace in the embodiments of the present disclosure is improved by at least 36% with respect to the related art.

In a fourth embodiment, referring to FIG. 28, the arrangement of the plurality of sub-pixels of the display substrate is GGRB as an example. In this implementation, each pixel includes one blue sub-pixel B, one red sub-pixel R, and two green sub-pixels G.

In FIG. 28, since a distance between two green sub-pixels G is relatively close, the two green sub-pixels G can be regarded as one object, i.e., the two green sub-pixels G share one dummy reference pattern. In some embodiments, a minimum external pattern of the two green sub-pixels G is first determined, and a dummy reference pattern is determined based on the light-emitting region of the blue sub-pixel B, the light-emitting region of the red sub-pixel R, and the minimum external pattern. The length of the light-emitting region of the red sub-pixel R in the second direction Y is the longest in the second direction Y among the lengths of the light-emitting region of the three sub-pixels in the second direction Y. The length of the light-emitting region of the blue sub-pixel B in the first direction X is the longest length among the lengths of the light-emitting region of the three sub-pixels in the first direction X.

For the mask for preparing the touch electrode structure corresponding to the display substrate shown in FIG. 28, the design of an opening in the mask is as follows: the length of the light-emitting region of the blue sub-pixel B in the second direction Y serves as the length of the dummy reference pattern in the second direction Y, and the length of the light-emitting region of the red sub-pixel R in the first direction X serves as the length of the dummy reference pattern in the first direction X. The length of the light-emitting region of the red sub-pixel R in the first direction X is the longest length of the three. Further, the centers of the respective dummy reference patterns overlap with the centers of the light-emitting regions of the respective sub-pixels, so as to design an opening of the mask thereof at the middle position of two adjacent dummy reference patterns.

The center of the first dummy reference pattern is positioned to overlap with the center of the light-emitting region of the blue sub-pixel B, the center of the second dummy reference pattern is positioned to overlap with the center of the light-emitting region of the red sub-pixel R, and the center of the third dummy reference pattern is positioned to overlap with a center of the minimum external pattern.

Referring to FIG. 28, four rows of sub-pixels arranged in the first direction X are shown, and in each row of sub-pixels arranged in the first direction X, the blue sub-pixel B, the red sub-pixel R, and the two green sub-pixels G are arranged sequentially. In addition, the sub-pixels in two adjacent rows of sub-pixels are staggered in the first direction X. Referring to FIG. 28, for an opening formed between the blue sub-pixel B and the red sub-pixel R in the mask, a distance between the opening and the first dummy reference pattern is equal to a distance between the opening and the second dummy reference pattern. For an opening formed between the red sub-pixel R and the two green sub-pixels G in the mask, a distance between the opening and the adjacent second dummy reference pattern is equal to a distance between the opening and the third dummy reference pattern. That is, in the first direction X, an opening of a touch trace formed between any two adjacent sub-pixels in the mask is provided at a midline position of two adjacent dummy reference patterns.

In the touch electrode structure prepared by the mask designed by the design method provided by the embodiments of the present disclosure, the distance detection results in that a distance a4 between the touch trace 10 and the touch trace 11 is 38 μm, a distance b4 between the touch trace 11 and the touch trace 12 is 41.1 μm, and a distance c4 between the touch trace 12 and the touch trace 13 is 41.7 μm. i.e., a4:b4=0.92, a4:c4=0.91, b4:c4=0.99. Moreover, in FIG. 28, the box with length k4 and width j4 is the smallest repeating unit containing a set of GGRB pixels, with k4=120.8 μm and j4=120.8 μm. a4+b4+c4=k4.

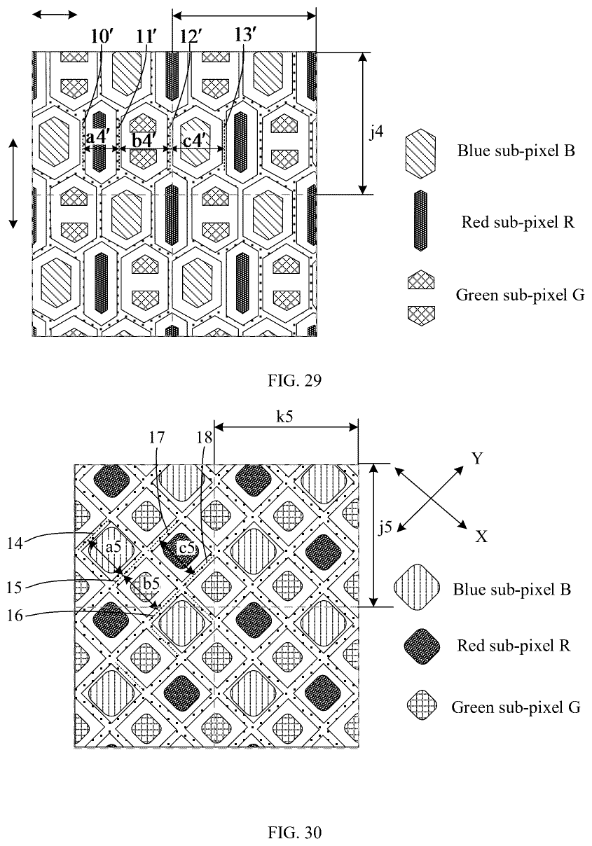

Referring to the related art of FIG. 29, a distance between the touch trace 11′ and the light-emitting region of the red sub-pixel R is equal to a distance between the touch trace 11′ and the light-emitting region of the green sub-pixel G. A distance between the touch trace 12′ and the light-emitting region of the green sub-pixel G is equal to a distance between the touch trace 12′ and the light-emitting region of the blue sub-pixel B. That is, in the first direction X, the touch trace is provided at a midline position of the light-emitting regions of two adjacent sub-pixels.

In the solution of the related art, the distance detection results in that a distance a4′ between the touch trace 10′ and the touch trace 11′ is 31.2 μm, and a distance b4′ between the touch trace 11′ and the touch trace 12′ is 43.6 μm. The distance c4′ between the touch trace 12′ and the touch trace 13′ is 46 μm. That is, a4′:b4′=0.72, a4′:c4′=0.68, b4′:c4′=0.95. a4′+b4′+c4′=j4.

Combined with the ratio of the distance between the touch traces in embodiments of the present disclosure and the ratio of the distance between the touch traces in the related art, the ratio of the distance between the touch trace in embodiments of the present disclosure is improved by 30% for a4:b4 with respect to a4′:b4′, improved by 23% for a4:c4 with respect to a4′:c4′, and improved by 4% for b4:c4 with respect to b4′:c4′. As a result, the uniformity of the touch trace in the embodiments of the present disclosure is improved by at least 4% with respect to the related art.

In a fifth embodiment, referring to FIG. 30, the arrangement of the plurality of sub-pixels of the display substrate is a circular GGRB as an example. In this implementation, each pixel includes one blue sub-pixel B, one red sub-pixel R, and one green sub-pixel G.

In FIG. 30, in the light-emitting regions of the three sub-pixels, the light-emitting region of the blue sub-pixel B has the largest area. Therefore, the pattern of the light-emitting region of the blue sub-pixel B is selected as a dummy reference pattern (respective dummy reference patterns are not shown in the drawings). A center of the first dummy reference pattern is positioned to overlap with a center of the light-emitting region of the blue sub-pixel B, a center of the second dummy reference pattern is positioned to overlap with a center of the light-emitting region of the red sub-pixel R, and a center of the third dummy reference pattern is positioned to overlap with a center of the light-emitting region of the green sub-pixel G.

Referring to FIG. 30, eight rows of sub-pixels arranged in the second direction Y are shown, and a plurality of sub-pixels included in each row are arranged in the first direction X. In the two adjacent rows of sub-pixels in the second direction Y, one row of sub-pixels is of blue sub-pixels B and green sub-pixels G that are staggered, and the other row of sub-pixels is of green sub-pixels G and red sub-pixels R that are staggered. For an opening of a touch trace formed between the blue sub-pixel B and the green sub-pixel G in the mask, a distance between the opening and the first dummy reference pattern is equal to a distance between the opening and the third dummy reference pattern. For an opening of a touch trace formed between the green sub-pixel G and the red sub-pixel R in the mask, a distance between the opening and the third dummy reference pattern is equal to a distance between the opening and the second dummy reference pattern. That is, for an opening of a touch trace formed between any two adjacent sub-pixels in the mask, the opening is provided at a center position of the dummy reference pattern where the light-emitting regions of the two sub-pixels are located.

In the touch electrode structure prepared by the mask designed by the design method provided by the embodiments of the present disclosure, the distance detection results in that a distance a5 between the touch trace 14 and the touch trace 15, a distance b5 between the touch trace 15 and the touch trace 16, and a distance c5 between the touch trace 17 and the touch trace 18 are all equal to 34.36 μm. i.e., a5=b5=c5=34.36 μm, a5:b5=1, a5:c5=1, b5:c5=1. Moreover, in FIG. 30, the box with length k5 and width j5 is the smallest repeating unit containing a set of RGB pixels and a sensor, with k5=98.32 um and j5=98.32 μm.

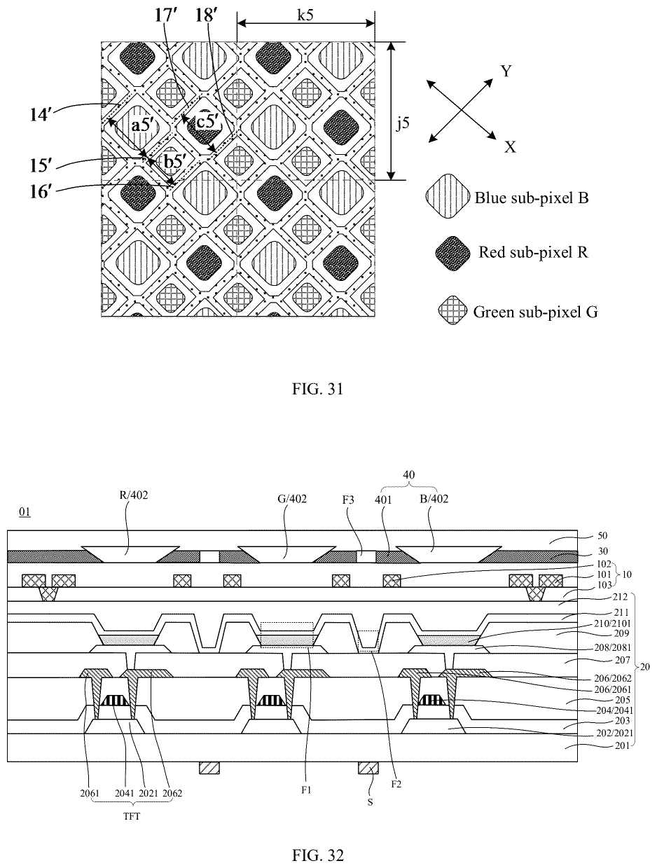

Referring to the related art of FIG. 31, a touch trace is provided at a midline position of the light-emitting regions of two adjacent sub-pixels. The distance detection results in that, in the solution of the related art, a distance a5′ between the touch trace 14′ and the touch trace 15′ is 40.4 um, and a distance b5′ between the touch trace 15′ and the touch trace 16′ is 28.3 μm. A distance c5′ between the touch trace 17′ and the touch trace 18′ is 37.1 μm. i.e., a5′:b5′=1.43, a5′:c5′=1.09, and b5′:c5′=0.76.

Combined with the ratio of the distance between the touch traces in embodiments of the present disclosure and the ratio of the distance between the touch traces in the related art, the ratio of the distance between the touch trace in embodiments of the present disclosure is improved by 43% for a5:b5 with respect to a5′:b5′, improved by 9% for a5:c5 with respect to a5′:c5′, and improved by 24% for b5:c5 with respect to b5′:c5′. As a result, the uniformity of the touch trace in the embodiments of the present disclosure is improved by at least 9% with respect to the related art.

In the embodiments of the present disclosure, by causing an opening in the mask to be disposed at a midline position of two adjacent dummy reference patterns may mean that a distance between the opening and one of the two adjacent dummy reference patterns and a distance between the opening and the other of the two adjacent dummy reference patterns are approximately the same. For example, the opening and the two adjacent dummy reference patterns are at exactly equal distances, or, the opening and the two adjacent dummy reference patterns are at exactly equal distances for fine adjustment. The maximum adjustment distance when the opening for fine adjustment may be less than 5% of the size of the dummy reference pattern.

In addition, the embodiments of the present disclosure illustrate the method for designing the openings in the mask only in the several embodiments described above as examples. The light-emitting region of the sub-pixel and the shape of the sensor may be a circle, a rectangle, or any polygon.

The method for designing the openings in the mask in the embodiments of the present disclosure is not limited by the shape, size, number, and distance of the light-emitting regions of the sub-pixels or the sensors, which can maximize the uniformity of the arrangement of the touch traces. Moreover, the solution of the embodiments of the present disclosure can effectively improve the touch uniformity without increasing the power consumption of the touch chip, which has no limit on the size of the display device and no limit on the process capability.

In summary, the embodiments of the present disclosure provide a method for preparing a touch electrode structure. In a plurality of touch traces included in a first touch electrode and in a second touch electrode that are insulated from each other in the touch electrode structure prepared by this method, a ratio of a first distance between a first touch trace and a second touch trace in a first direction to a second distance between the second touch trace and a third touch trace in a second direction is close to 1. That is, the first touch trace, the second touch trace, and the third touch trace that are arranged in the first direction and adjacent to each other are arranged more uniformly, which can improve the uniformity of the field strength of the touch panel, improve the uniformity and sensitivity of the capacitive sensing signal of the touch panel, thereby improving the touch effect of the touch panel, and avoiding visibility problems of the display device simultaneously.

FIG. 1 and FIG. 9 are partial cross-sectional schematic diagrams of a touch panel according to some embodiments of the present disclosure. Referring to FIG. 1 and FIG. 9, the touch panel includes a display substrate 20 and a touch electrode structure 10 disposed on the display substrate 20 as provided in the above embodiments.

In the embodiments of the present disclosure, the display substrate 20 may include a plurality of sub-pixels that are arranged in an array. The plurality of sub-pixels form a plurality of pixels. Each pixel includes at least one first color sub-pixel, one second color sub-pixel, and one third color sub-pixel. The first color is blue, the second color is red, and the third color is green.

In an optional case, referring to FIG. 22 and FIG. 24, each pixel includes a blue sub-pixel, a red sub-pixel, and a green sub-pixel. Alternatively, referring to FIG. 30, each pixel includes a blue sub-pixel B, a red sub-pixel R, and two green sub-pixels G, and the two green sub-pixels G are separated by a distance of greater than 5 μm.

In the case that the shape of the light-emitting region of the blue sub-pixel B, the shape of the light-emitting region of the red sub-pixel R, and the shape of the light-emitting region of the green sub-pixels are the same, the dummy reference pattern corresponding to each sub-pixel may be determined based on the area of the plurality of sub-pixels. Further, after the setting position of the opening of the mask is determined by the dummy reference pattern, the plurality of touch traces in the touch electrode structure prepared by the mask form the plurality of mesh structures. The plurality of mesh structures include at least a plurality of sub-pixel target mesh structures, each sub-pixel target mesh structure may surround the light-emitting region of one sub-pixel.

For a light-emitting region of each sub-pixel, a minimum distance, in the first direction X, between the light-emitting region of the sub-pixel and a touch trace in a mesh structure surrounding the light-emitting region of the sub-pixel is negatively correlated with an area of the light-emitting region of the sub-pixel. That is, in the case that the area of the light-emitting region of the blue sub-pixel B is larger than the area of the light-emitting region of the red sub-pixel R, and the area of the light-emitting region of the red sub-pixel R is larger than the area of the light-emitting region of the green sub-pixel G, a minimum distance, in the first direction X, between the light-emitting region of the blue sub-pixel and a touch trace in a mesh structure surrounding the light-emitting region of the blue sub-pixel is less than a minimum distance, in the first direction X, between the light-emitting region of the red sub-pixel and a touch trace in a mesh structure surrounding the light-emitting region of the red sub-pixel. Moreover, a minimum distance, in the first direction X, between the light-emitting region of the red sub-pixel and a touch trace in a mesh structure surrounding the light-emitting region of the red sub-pixel is less than a minimum distance, in the first direction X, between the light-emitting region of the green sub-pixel and a touch trace in a mesh structure surrounding the light-emitting region of the green sub-pixel.

In another optional case, regardless of whether the shape of the light-emitting region of the blue sub-pixel, the shape of the light-emitting region of the red sub-pixel, and the shape of the light-emitting region of the green sub-pixel are the same, the dummy reference pattern corresponding to each sub-pixel may be determined based on the lengths of the plurality of sub-pixels. Further, after the setting position of the opening of the mask is determined by the dummy reference pattern, the plurality of touch traces in the touch electrode structure prepared by the mask form the plurality of mesh structures. The plurality of mesh structures include at least a plurality of sub-pixel target mesh structures, each sub-pixel target mesh structure surrounding a light-emitting region of at least one sub-pixel.

For the light-emitting region of each sub-pixel, a minimum distance, in the first direction X, between the light-emitting region of the sub-pixel and a touch trace in a mesh structure surrounding the light-emitting region of the sub-pixel is negatively correlated with the length of the light-emitting region of the sub-pixel in the first direction X. That is, in the case that the length of the light-emitting region of the blue sub-pixel B in the first direction X is greater than the length of the light-emitting region of the red sub-pixel R in the first direction X, and the length of the light-emitting region of the red sub-pixel R in the first direction X is greater than the length of the light-emitting region of the green sub-pixel G in the first direction X, a minimum distance, in the first direction X, between the light-emitting region of the blue sub-pixel and a touch trace in a mesh structure surrounding the light-emitting region of the blue sub-pixel is less than a minimum distance, in the first direction X, between the light-emitting region of the red sub-pixel and a touch trace in a mesh structure surrounding the light-emitting region of the red sub-pixel. Moreover, a minimum distance, in the first direction X, between the light-emitting region of the red sub-pixel and a touch trace in a mesh structure surrounding the light-emitting region of the red sub-pixel is less than a minimum distance, in the first direction X, between the light-emitting region of the green sub-pixel and a touch trace in a mesh structure surrounding the light-emitting region of the green sub-pixel.

Referring to FIG. 26, each pixel includes one blue sub-pixel, one red sub-pixel, and one green sub-pixel. Each mesh structure formed by a plurality of touch traces in the touch electrode structure surrounds the light-emitting region of one sub-pixel.

Alternatively, referring to FIG. 28, each pixel includes one blue sub-pixel, one red sub-pixel, and two green sub-pixels. A distance between the light-emitting regions of the two green sub-pixels is less than 14 um. The plurality of sub-pixel target mesh structures include a first-type mesh structure and a second-type mesh structure. The first-type mesh structure surrounds the light-emitting region of the red sub-pixel or surrounds the light-emitting region of the blue sub-pixel. The second-type mesh structure surrounds the light-emitting regions of two green sub-pixels, and the light-emitting regions of the two green sub-pixels are arranged in the second direction Y.

In the embodiment of the present disclosure, referring to FIG. 22 and FIG. 24, the display substrate 20 also includes a plurality of sensors S. The plurality of mesh structures formed by the plurality of touch traces also includes a plurality of sensor target mesh structures. Each sensor target mesh structure surrounds one sensor S.

A minimum distance, in the first direction X, between the sensor S and a touch trace in a sensor target mesh structure surrounding the sensor is negatively correlated with the length of the sensor S in the first direction X. That is, the greater the length of the sensor S in the first direction X, the smaller the minimum distance, in the first direction S, between the sensor and the touch trace in the sensor target mesh structure surrounding the sensor; and the smaller the length of the sensor S in the first direction X, the greater the minimum distance, in the first direction S, between the sensor and the touch trace in the sensor target mesh structure surrounding the sensor.

FIG. 32 is a partial cross-sectional schematic diagram of a touch panel according to some embodiments of the present disclosure. As can be seen with reference to FIG. 32, the display substrate 20 includes a backplane 201, a sensor S disposed on a side of the backplane, a semiconductor layer 202, a gate insulating layer (GI) 203, a gate layer 204, an inter-level dielectric layer (ILD) 205, a source-drain layer 206, a planarization layer (PLN) 207, an anode layer 208, a pixel definition layer (PDL) 209, a light-emitting layer 210, a cathode layer 211, and an encapsulation layer 212.

In the embodiments of the present disclosure, each sub-pixel included in the display substrate 20 may include a pixel circuit and a light-emitting unit. The pixel circuit may be used to provide a driving signal for the light-emitting unit, and the light-emitting unit may emit light under the control of the driving signal provided by the pixel circuit.

The semiconductor layer 202, the gate layer 204, and the source-drain layer 206 are used to form a thin film transistor (TFT) included in the pixel circuit in the sub-pixel. The semiconductor layer 202 includes a plurality of semiconductor patterns 2021 that are spaced apart, and each TFT includes one semiconductor pattern 2021. The gate layer 204 includes a plurality of gate patterns 2041 that are spaced apart, and each TFT includes one gate pattern 2041. An orthographic projection of the gate pattern 2041 on the backplane 201 partially overlaps an orthographic projection of the semiconductor pattern 2021 on the backplane 201, and the overlapping region is a channel region of the TFT. The source-drain layer 206 includes a plurality of source patterns 2061 and a plurality of drain patterns 2062 corresponding to the plurality of source patterns 2061 Each TFT includes one source pattern 2061 and one corresponding drain pattern 2062. Each of the source patterns 2061 and the corresponding drain pattern 2062 is connected to the semiconductor pattern 2021 in the TFT through vias in the gate insulating layer 203 and the interlayer dielectric layer 205.

In addition, the anode layer 208, the pixel definition layer 209, the light-emitting layer 210, and the cathode layer 211 are used to form a light-emitting unit in the sub-pixels. The anode layer 208 includes a plurality of anode patterns 2081 that are spaced apart. The pixel definition layer 209 is provided with a plurality of hollowed-out regions F1, each of which is used to expose one of the anode patterns 2081. The light-emitting layer 210 includes a plurality of light-emitting patterns 2101 that are spaced apart, each of which is in contact with one anode pattern 2081 exposed by the hollowed-out region F1. The cathode layer 211 is designed as a whole layer, contacting all of the plurality of light-emitting patterns 2101 included in the light-emitting layer 210. The portion of the light-emitting pattern 2101 that is in contact with both the anode pattern 2081 and the cathode layer 211 forms the light-emitting region of the sub-pixel.

As can be seen with reference to FIG. 32, the pixel definition layer 209 also be provided with a first opening region F2, and an orthographic projection of the sensor S on the backplane 201 is located within an orthographic projection of the first opening region F2 on the backplane 201. By this design, the pixel definition layer 209 can be avoided to affect the reception of signals (e.g., reception of optical signals) by the sensor S.

Referring to FIG. 32, the touch electrode structure 10 is disposed on a side of the encapsulation layer 212 away from the backplane 201. An orthographic projection of a touch trace M in the first touch electrode 101 and the second touch electrode 102 included in the touch electrode structure 10 on the backplane 201 does not overlap with the orthographic projection of the light-emitting region of the sub-pixel on the backplane 201, so as to avoid affecting the normal emission of sub-pixels. Moreover, the orthographic projection of the touch trace M on the backplane 201 does not overlap with the orthographic projection of the sensor S on the backplane 201, avoiding any influence of the touch trace M on the reception of the signal by the sensor S. In some embodiments, the orthographic projection of the touch trace M on the backplane 201 does not overlap with an orthographic projection of the hollowed-out region F1 in the pixel definition layer 209 on the backplane 201, which in turn enables the orthographic projection of the touch trace M on the backplane 201 to not overlap with the orthographic projection of the light-emitting region of the sub-pixel on the backplane 201. In addition, the orthographic projection of the touch trace M on the backplane 201 does not overlap with an orthographic projection of the first opening region F2 in the pixel definition layer 209 on the backplane 201, which in turn enables the orthographic projection of the touch trace M on the backplane 201 to not overlap with the orthographic projection of the sensor S on the backplane 201.

Referring to FIG. 32, the touch panel 01 also includes an insulating layer 30, a color film layer 40, and a planarization layer 50 disposed on a side of the touch electrode structure 10 away from the backplane 201. The insulating layer 30 is used to insulate the touch electrode structure 10 and the color film layer 40. The planarization layer 50 is used to planarize the color film layer 40.

The colored film layer 40 includes a shading portion 401 and a plurality of filters 402 of different colors. The shading portion 401 has a second opening region F3, and an orthographic projection of the second opening region F3 on the backplane 201 covers the orthographic projection of the sensor S on the backplane 201, thereby avoiding the effect of the shading portion 401 on the signal received by the sensor S. Moreover, an orthographic projection of each filter 402 on the backplane 201 covers a light-emitting region of a corresponding sub-pixel, the light emitted from the sub-pixel can be ejected after passing through the filter 402, and the light ejected after passing through the filter 402 is of the same color as the filter 402. The filters 402 of different colors include a blue filter B, a red filter R, and a green filter G. Three filters are shown in FIG. 32, and from left to right are the red filter R, the green filter G, and the blue filter B. As a result, the color of the light that is emitted from the light-emitting region of the leftmost sub-pixel, passes through the red filter R, and emits from the red filter R is red, the color of the light that is emitted from the light-emitting region of the middle sub-pixel, passes through the green filter G, and emits from the green filter G is green, and the color of the light that is emitted from the light-emitting region of the rightmost sub-pixel, passes through the blue filter B, and emits from the blue filter B is blue.

The touch panel 01 provided by the embodiments of the present disclosure may have essentially the same technical effect as the touch electrode structure 10 described in the above embodiments, and therefore, for the purpose of brevity, the technical effect of the touch panel 01 will not be repeated herein.

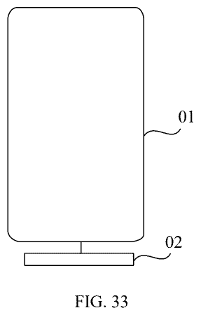

FIG. 33 is a schematic structural diagram of a display device according to some embodiments of the present disclosure. Referring to FIG. 33, the display device includes a power supply assembly 02 and a touch panel 01 as provided in the above embodiments. The power supply assembly 02 is configured to supply power to the touch panel 01.

In some embodiments, the display device may be a low-temperature polycrystalline oxide (LTPO) display device, a low-temperature poly-silicon (LTPS) display device, or an organic light-emitting display (OLED) display device. The display device may be any suitable display device including, but not limited to, cell phones, tablet computers, televisions, monitors, laptops, digital photo frames, navigators, e-books, and any other product or component with a display function.

As the display device has essentially the same technical effect as the touch electrode structure described in the previous embodiments, the technical effect of the display device will not be repeated here for the purpose of brevity.

The terms used in the embodiments of the present disclosure are used only for the purpose of explaining the embodiments of the present disclosure and are not intended to limit the present disclosure. Unless otherwise defined, technical terms or scientific terms used in the embodiments of the present disclosure should have the ordinary meaning understood by a person of ordinary skill in the field to which the present disclosure belongs.

The terms used in the embodiments of the present disclosure are merely intended for the purpose of explaining the embodiments of the present disclosure and are not intended to limit the present disclosure. Unless otherwise defined, technical or scientific terms used in the embodiments of the present disclosure shall have the same meanings as commonly understood by a person of ordinary skill in the art to which the present disclosure belongs. The terms “first,” “second,” “third,” and the like used in the specification and the claims of the present disclosure do not indicate any order, number, or importance, but are used only to distinguish between different components. Likewise, similar words “a” or “an” do not indicate a quantity limitation, but indicate that there is at least one. The terms “include” or “comprise” and the like are intended to indicate that the elements or objects before “include” or “comprise” encompass the elements or objects listed after “include” or “comprise” and their equivalents, and do not exclude other elements or objects. The terms “connect” or “connected” and the like are not limited to physical or mechanical connections, but may include electrical connections, whether direct or indirect. The terms “upper,” “lower,” “left,” “right,” etc. are only used to represent relative position relationships, and when the absolute position of the object to be described changes, the relative position relationship may also be changed accordingly.

The foregoing descriptions are merely optional embodiments of the present disclosure and are not intended to limit the present disclosure. Any modification, equivalent replacement, and improvement within the spirit and principle of the present disclosure shall be included within the protection scope of the present disclosure.

What is claimed is:

1. A touch electrode structure, applied in a touch panel, and comprising a first touch electrode and a second touch electrode insulated from the first touch electrode; wherein
the first touch electrode and the second touch electrode each comprise a plurality of touch traces, wherein the plurality of touch traces comprise a first touch trace, a second touch trace, and a third touch trace that are arranged sequentially and adjacent in a first direction, a ratio of a first distance between the first touch trace and the second touch trace in the first direction to a second distance between the second touch trace and the third touch trace in the first direction ranging from 0.9 to 1.1;
wherein the first direction is one arrangement direction of a plurality of sub-pixels that are arranged in an array and of a display substrate in the touch panel.

2. The touch electrode structure according to claim 1, wherein the plurality of touch traces form a plurality of mesh structures with each of the mesh structures being in a hexagonal shape, the plurality of mesh structures comprising a first target mesh structure and a second target mesh structure that are arranged and adjacent in the first direction;
wherein the first touch trace is a touch trace, away from the second target mesh structure, of the first target mesh structure, the second touch trace is a touch trace shared by the first target mesh structure and the second target mesh structure, and the third touch trace is a touch trace, away from the first target mesh structure, of the second target mesh structure.

3. The touch electrode structure according to claim 2, wherein the first direction is a column direction of the sub-pixels in the touch panel or a row direction of the sub-pixels in the touch panel;
wherein the plurality of mesh structures further comprise a third target mesh structure adjacent to both the first target mesh structure and the second target mesh structure, wherein the third target mesh structure and the second touch trace are arranged in a second direction, the second direction intersecting with the first direction; and
a touch trace shared by the third target mesh structure and the first target mesh structure intersects with both the first direction and the second direction, and a touch trace shared by the third target mesh structure and the second target mesh structure intersects with both the first direction and the second direction.

4. (canceled)

5. The touch electrode structure according to claim 1, wherein the plurality of touch traces further comprise a fourth touch trace and a fifth touch trace that are arranged and adjacent in the first direction, wherein the fourth touch trace and the fifth touch trace are disposed on a side, away from the first touch trace, of the third touch trace, and the fourth touch trace and the third touch trace are adjacent in the first direction; and the plurality of touch traces form a plurality of first mesh structure groups and a plurality of second mesh structure groups, wherein the plurality of first mesh structure groups and the plurality of second mesh structure groups are arranged alternately in a second direction, the second direction being perpendicular to the first direction; wherein
each of the first mesh structure groups comprises a fourth target mesh structure, a fifth target mesh structure, a sixth target mesh structure, and a seventh target mesh structure that are arranged sequentially and adjacent in the first direction, wherein the first touch trace is a touch trace, away from the fifth target mesh structure, of the fourth target mesh structure, the second touch trace is a touch trace shared by the fourth target mesh structure and the fifth target mesh structure, the third touch trace is a touch trace shared by the fifth target mesh structure and the sixth target mesh structure, the fourth touch trace is a touch trace shared by the sixth target mesh structure and the seventh target mesh structure, and the fifth touch trace is a touch trace, away from the sixth target mesh structure, of the seventh target mesh structure; and
each of the second mesh structure groups comprises an eighth target mesh structure and a ninth target mesh structure that are arranged sequentially and adjacent in the first direction, wherein the first touch trace is also a touch trace, away from the ninth target mesh structure, of the eighth target mesh structure, the third touch trace is also a touch trace shared by the eighth target mesh structure and the ninth target mesh structure, and the fifth touch trace is also a touch trace, away from the eighth target mesh structure, of the ninth target mesh structure.

6. The touch electrode structure according to claim 5, wherein a ratio of a third distance between the third touch trace and the fourth touch trace in the first direction to the first distance and a ratio of the third distance to the second distance both range from 0.9 to 1.1; a ratio of a fourth distance between the fourth touch trace and the fifth touch trace in the first direction to the first distance and a ratio of the fourth distance to the second distance both range from 0.9 to 1.1; and
a ratio of a fifth distance between the first touch trace and the third touch trace in the first direction to a sixth distance between the third touch trace and the fifth touch trace in the first direction ranges from 0.9 to 1.1.

7. The touch electrode structure according to claim 5, wherein any one mesh structure in the first mesh structure groups and the second mesh structure groups is in a quadrilateral shape; the plurality of touch traces further comprise a sixth touch trace, a seventh touch trace, and an eighth touch trace arranged and adjacent in the second direction; and the plurality of first mesh structure groups comprise a first target mesh structure group, and the plurality of second mesh structure groups comprise a second target mesh structure group adjacent to the first target mesh structure group; wherein
the sixth touch trace is a touch trace shared by a plurality of mesh structures in the first target mesh structure group on a side away from the second target mesh structure group, the seventh touch trace is a touch trace shared by the plurality of mesh structures in the first target mesh structure group and a plurality of mesh structure in the second target mesh structure group, and the eighth touch trace is a touch trace shared by a plurality of mesh structures in the second target mesh structure group on a side away from the first target mesh structure group; and
a ratio of a seventh distance between the sixth touch trace and the seventh touch trace in the second direction to an eighth distance between the seventh touch trace and the eighth touch trace in the second direction ranges from 0.9 to 1.1.

8. The touch electrode structure according to claim 1, wherein the plurality of touch traces form a plurality of mesh structures with each of the mesh structures being in a quadrilateral shape; wherein
the plurality of mesh structures comprise a tenth target mesh structure and an eleventh target mesh structure arranged and adjacent in the first direction, wherein the first touch trace is a touch trace, away from the eleventh target mesh structure, of the tenth target mesh structure, the second touch trace is a touch trace shared by the tenth target mesh structure and the eleventh target mesh structure, and the third touch trace is a touch trace, away from the tenth target mesh structure, of the eleventh target mesh structure;
wherein the plurality of touch traces further comprise a sixth touch trace, a seventh touch trace, and an eighth touch trace that are arranged sequentially and adjacent in a second direction; wherein
a ratio of a seventh distance between the sixth touch trace and the seventh touch trace in the second direction to an eighth distance between the seventh touch trace and the eighth touch trace in the second direction ranges from 0.9 to 1.1.

9. (canceled)

10. The touch electrode structure according claim 1, wherein the plurality of touch traces further comprise a ninth touch trace and a tenth touch trace; wherein
each of the ninth touch trace and the tenth touch trace is any one touch trace other than the second touch trace in the plurality of touch traces, and the ninth touch trace and the tenth touch trace are arranged and adjacent in the first direction; and
a ratio of a distance between the ninth touch trace and the tenth touch trace in the first direction to the first distance and a ratio of the distance between the ninth touch trace and the tenth touch trace in the first direction to the second distance both range from 0.9 to 1.1.

11. The touch electrode structure according to claim 1, wherein the display substrate in the touch panel comprises the plurality of sub-pixels and a plurality of sensors; a plurality of mesh structures formed by the plurality of touch traces comprise a sub-pixel target mesh structure and a sensor target mesh structure, the sub-pixel target mesh structure surrounding a light-emitting region of at least one of the sub-pixels, and the sensor target mesh structure surrounding at least one of the sensors; wherein
the sub-pixel target mesh structure comprises an eleventh touch trace and a twelfth touch trace arranged in the first direction, and the sensor target mesh structure comprises a thirteenth touch trace and a fourteenth touch trace arranged in the first direction;
wherein a ratio of a ninth distance between the eleventh touch trace and the twelfth touch trace in the first direction to a tenth distance between the thirteenth touch trace and the fourteenth touch trace in the first direction ranges from 0.9 to 1.1;
a ratio of the ninth distance to the first distance and a ratio of the ninth distance to the second distance both range from 0.9 to 1.1; and
a ratio of the tenth distance to the first distance and a ratio of the tenth distance to the second distance both range from 0.9 to 1.1.

12. (canceled)

13. A method for preparing a touch electrode structure, wherein the touch electrode structure is applied in a touch panel, and comprises a first touch electrode and a second touch electrode insulated from the first touch electrode; and the method comprises:
forming a touch electrode film; and
acquiring a plurality of touch traces comprised in the first touch electrode and/or the second touch electrode by patterning the touch electrode film using a mask, wherein the plurality of touch traces comprise a first touch trace, a second touch trace, and a third touch trace that are arranged sequentially and adjacent in a first direction, and a ratio of a first distance between the first touch trace and the second touch trace in the first direction to a second distance between the second touch trace and the third touch trace in the first direction ranges from 0.9 to 1.1; wherein the first direction comprises one arrangement direction of a plurality of sub-pixels that are arranged in an array and of a display substrate in the touch panel.

14. The method according to claim 13, wherein the plurality of sub-pixels of the display substrate in the touch panel form a plurality of pixels, and each of the pixels comprises one first color sub-pixel, one second color sub-pixel, and one third color sub-pixel; the mask is provided with a plurality of openings for forming the plurality of touch traces; and a design process of a target opening in the plurality of openings comprises:
positioning a center of a first dummy reference pattern to overlap with a center of a light-emitting region of the first color sub-pixel, positioning a center of a second dummy reference pattern to overlap with a center of a light-emitting region of the second color sub-pixel, positioning a center of a third dummy reference pattern to overlap with a center of a light-emitting region of the third color sub-pixel, wherein a shape and a size of each dummy reference pattern are a same, and the shape and size of each dummy reference pattern are determined based on a shape and a size of a light-emitting region of each of the first color sub-pixel, the second color sub-pixel, and the third color sub-pixel; and the first dummy reference pattern, the second dummy reference pattern, and the third dummy reference pattern have a first target reference pattern and a second target reference pattern that are adjacent; and
designing a target opening in a region, of the mask, between the first target reference pattern and the second target reference pattern, wherein a distance between the target opening and the first target reference pattern is equal to a distance between the target opening and the second target reference pattern; or
wherein the plurality of sub-pixels of the display substrate in the touch panel form a plurality of pixels, each of the pixels comprises one first color sub-pixel, one second color sub-pixel, and one third color sub-pixel, and the display substrate further comprises a plurality of sensors; the mask is provided with a plurality of openings for forming the plurality of touch traces; and a design process of a target opening in the plurality of openings comprises:
positioning a center of a first dummy reference pattern to overlap with a center of a light-emitting region of the first color sub-pixel, positioning a center of a second dummy reference pattern to overlap with a center of a light-emitting region of the second color sub-pixel, positioning a center of a third dummy reference pattern to overlap with a center of a light-emitting region of the third color sub-pixel, positioning a center of a fourth dummy reference pattern to overlap with a center of a light-emitting region of one of the sensors, wherein a shape and a size of each dummy reference pattern are a same, and the shape and size of each dummy reference pattern are determined based on a shape and a size of a light-emitting region of each of the first color sub-pixel, the second color sub-pixel, and the third color sub-pixel; a the first dummy reference pattern, the second dummy reference pattern, the third dummy reference pattern, and the fourth dummy reference pattern have a first target reference pattern and a second target reference pattern that are adjacent; and
designing a target opening in a region, of the mask, between the first target reference pattern and the second target reference pattern, wherein a distance between the target opening and the first target reference pattern is equal to a distance between the target opening and the second target reference pattern.

15. (canceled)

16. The method according to claim 14, wherein each of the pixels comprises one first color sub-pixel, one second color sub-pixel, and one third color sub-pixel; wherein a shape of a light-emitting region of the first color sub-pixel, a shape of a light-emitting region of the second color sub-pixel, and a shape of a light-emitting region of the third color sub-pixel are a same; and an area of the light-emitting region of the first color sub-pixel, an area of the light-emitting region of the second color sub-pixel, and an area of the light-emitting region of the third color sub-pixel are reduced sequentially;
the shape of each dummy reference pattern is a same as the shape of the light-emitting region of the first color sub-pixel, and an area of each dummy reference pattern is greater than or equal to the area of the light-emitting region of the first color sub-pixel.

17. The method according to claim 14, wherein a length of each dummy reference pattern in the first direction is greater than or equal to a longest length among a length of the light-emitting region of the first color sub-pixel in the first direction, a length of the light-emitting region of the second color sub-pixel in the first direction, and a length of the light-emitting region of the third color sub-pixel in the first direction;
a length of each dummy reference pattern in a second direction is greater than or equal to a longest length among a length of the light-emitting region of the first color sub-pixel in the second direction, a length of the light-emitting region of the second color sub-pixel in the second direction, and a length of the light-emitting region of the third color sub-pixel in the second direction, the second direction being perpendicular to the first direction; and
the shape of the dummy reference pattern is a same as at least one of the light-emitting region of the first color sub-pixel, the light-emitting region of the second color sub-pixel, or the light-emitting region of the third color sub-pixel.

18. The method according to claim 14, wherein each of the pixel comprises one first color sub-pixel, one second color sub-pixel, and two third color sub-pixels, and a distance between light-emitting regions of the two third color sub-pixels is less than 14 microns;
a length of each dummy reference pattern in a first direction is a first target length, the first target length being greater than or equal to a longest length among a length of the light-emitting region of the first color sub-pixel in the first direction, a length of the light-emitting region of the second color sub-pixel in the first direction, and a length of the target pattern in the first direction; wherein the target pattern is a minimum external pattern of the light-emitting regions of the two third color sub-pixels, a shape of the minimum external pattern being a same as a shape of the light-emitting region of the first color sub-pixel, and/or the shape of the minimum external pattern being a same as a shape of the light-emitting region of the second color sub-pixel;
a length of each dummy reference pattern in a second direction is a second target length, wherein the second target length is greater than or equal to a longest length among a length of the light-emitting region of the first color sub-pixel in the second direction, a length of the light-emitting region of the second color sub-pixel in the second direction, and a length of the target pattern in the second direction, the second direction being perpendicular to the first direction; and
the shape of the dummy reference pattern is a same as at least one of a light-emitting region of the first color sub-pixel, a light-emitting region of the second color sub-pixel, or the target pattern.

19. A touch panel, comprising a display substrate and a touch electrode structure, wherein the touch electrode structure is disposed on the display substrate; and
the touch electrode structure, applied in a touch panel, and comprising a first touch electrode and a second touch electrode insulated from the first touch electrode; wherein
the first touch electrode and the second touch electrode each comprise a plurality of touch traces, wherein the plurality of touch traces comprise a first touch trace, a second touch trace, and a third touch trace that are arranged sequentially and adjacent in a first direction, a ratio of a first distance between the first touch trace and the second touch trace in the first direction to a second distance between the second touch trace and the third touch trace in the first direction ranging from 0.9 to 1.1;
wherein the first direction is one arrangement direction of a plurality of sub-pixels that are arranged in an array and of a display substrate in the touch panel.

20. The touch panel according to claim 19, wherein the display substrate comprises a plurality of sub-pixels that are arranged in an array and form a plurality of pixels, each of the pixels comprising one first color sub-pixel, one second color sub-pixel, and one third color sub-pixel, wherein a shape of a light-emitting region of the first color sub-pixel, a shape of a light-emitting region of the second color sub-pixel, and a shape of a light-emitting region of the third color sub-pixel are a same; and the plurality of touch traces in the touch electrode structure form a plurality of mesh structures, wherein the plurality of mesh structures comprise a plurality of sub-pixel target mesh structures, each of the sub-pixel target mesh structures surrounding a light-emitting region of one sub-pixel;
wherein a minimum distance, in a first direction, between the light-emitting region of the sub-pixel and a touch trace in a sub-pixel target mesh structure surrounding the light-emitting region of the sub-pixel is negatively correlated with an area of the light-emitting region of the sub-pixel, the first direction comprising one arrangement direction of the plurality of sub-pixel arranged in an array.

21. The touch panel according to claim 19, wherein the display substrate comprises a plurality of sub-pixels that are arranged in an array and form a plurality of pixels, each of the pixels comprising one first color sub-pixel, one second color sub-pixel, and one third color sub-pixel; and the plurality of touch traces in the touch electrode structure form a plurality of mesh structures, wherein the plurality of mesh structures comprise a plurality of sub-pixel target mesh structures, each of the sub-pixel target mesh structures surrounding a light-emitting region of at least one sub-pixel;
wherein a minimum distance, in a first direction, between the light-emitting region of the sub-pixel and a touch trace in a sub-pixel target mesh structure surrounding the light-emitting region of the sub-pixel is negatively correlated with a length of the light-emitting region of the sub-pixel in the first direction, the first direction comprising one arrangement direction of the plurality of sub-pixel arranged in an array.

22. The touch panel according to claim 21, wherein each of the pixels comprises one first color sub-pixel, one second color sub-pixel, and two third color sub-pixels, and a distance between light-emitting regions of the two third color sub-pixels is less than 14 microns; and
the plurality of sub-pixel target mesh structures comprise a first-type mesh structure and a second-type mesh structure, wherein the first-type mesh structure surrounds a light-emitting region of the one first color sub-pixel or a light-emitting region of the one second color sub-pixel, the second-type mesh structure surrounds light-emitting regions of the two third color sub-pixels, and the light-emitting regions of two third color sub-pixels surrounded by the second-type mesh structure are arranged in a second direction, the second direction being perpendicular to the first direction.

23. The touch panel according to claim 20, wherein the display substrate further comprises a plurality of sensors; and the plurality of mesh structures further comprise a plurality of sensor target mesh structures, each of the sensor target mesh structures surrounding one sensor;
wherein a minimum distance, in a first direction, between the sensor and a touch trace in a sensor target mesh structure surrounding the sensor is negatively correlated with a length of the sensor in the first direction.

24. A touch display device, comprising a power supply assembly and the touch panel as defined in claim 19, wherein the power supply assembly is configured to supply power to the touch panel.
